(19) United States
(12) Patent Application Publication
(10) Pub. No.: US 2011/0210306 A1
(43) Pub. Date: Sep. 1, 2011

(54) MEMORY CELL THAT INCLUDES A CARBON-BASED MEMORY ELEMENT AND METHODS OF FORMING THE SAME

(76) Inventors: Yubao Li, Milpitas, CA (US); Er-Xuan Ping, Fremont, CA (US)

(21) Appl. No.: 12/714,359

(22) Filed: Feb. 26, 2010

(51) Int. Cl. H01L 45/00; H01L 21/20

(52) U.S. Cl. 257/3; 438/488; 257/E45.002; 257/E21.09

(57) ABSTRACT

A method of forming a reversible resistance-switching metal-carbon-metal (“MCM”) device is provided, the device including a first conducting layer, a second conducting layer, and a reversible resistance-switching element disposed between the first and second conducting layers, wherein the reversible resistance-switching element includes thermal CVD graphitic material and includes a highly resistive region that favors crack formation. Other aspects are also provided.

### TECHNICAL FIELD

This invention relates to non-volatile memories, and more particularly to a memory cell that includes a carbon-based memory element, and methods of forming the same.

### BACKGROUND

Non-volatile memories formed from reversible resistance switching elements are known. For example, U.S. patent application Ser. No. 11/968,154, filed Dec. 31, 2007, and titled “Memory Cell That Employs A Selectively Fabricated Carbon Nano-Tube Reversible Resistance Switching Element And Methods Of Forming The Same,” (the “'154 Application”) (Docket No. SD-MXA-241), which is incorporated by reference herein in its entirety for all purposes, describes a rewriteable non-volatile memory cell that includes a diode coupled in series with a carbon-based reversible resistivity switching material.

However, fabricating memory devices from carbon-based materials is technically challenging, and improved methods of forming memory devices that employ carbon-based materials are desirable.

### SUMMARY

In a first aspect of the invention, a reversible resistance-switching MCM device is provided, the MCM device including: (a) a first conducting layer; (b) a second conducting layer; and (c) a reversible resistance-switching element disposed between the first and second conducting layers, wherein the reversible resistance-switching element includes thermal CVD graphitic material and includes a highly resistive region that favors crack formation.

In a second aspect of the invention, a method of forming a reversible resistance-switching MCM structure is provided, the method including: (a) forming first and second conducting layers; and (b) forming a reversible resistance-switching element between the first and second conducting layers, wherein the reversible resistance-switching element includes a thermal CVD graphitic material and has a highly resistive region that favors crack formation.

In a third aspect of the invention, a method of forming a reversible resistance-switching MCM structure is provided, the method including: (a) forming a feature having a first width and a second width smaller than the first width; and (b) disposing a reversible resistance-switching element on a sidewall of the feature, wherein the reversible resistance-switching element includes thermal CVD graphitic material.

In a fourth aspect of the invention, a method of forming a reversible resistance-switching MCM structure is provided, the method including: (a) forming a first conducting layer; (b) forming a first insulating material layer above the first conducting layer; (c) forming a second insulating material layer above the first insulating material layer, the second insulating material being different than the first insulating material; (d) forming a second conducting layer above the second insulating layer; and (e) disposing a reversible resistance-switching element on the second conducting layer, the first insulating material layer and the second insulating material layer, wherein the reversible resistance-switching element includes thermal CVD graphitic material.

In a fifth aspect of the invention, a method of forming a memory cell is provided, the method including: (a) forming a first conductor; (b) forming a feature above the first conductor, the feature having a first portion having a first width and a second portion having a second width smaller than the first width; (c) forming a reversible resistance-switching element on a sidewall of the feature, wherein the reversible resistance-switching element includes thermal CVD graphitic material; and (d) forming a second conductor above the reversible resistance-switching element.

In a sixth aspect of the invention, a method of forming a memory cell is provided, the method including: (a) forming a first conductor; (b) forming a first insulating material layer above the first conductor, wherein the first insulating material layer has a first width; (c) forming a second insulating material layer above the first insulating layer, wherein the second insulating material is different from the first insulating material, and wherein the second insulating material layer has the first width; (d) shrinking the first insulating material layer to a second width smaller than the first width; (e) forming a reversible resistance-switching element on the shrunken first insulating material layer and the second insulating material layer, wherein the reversible resistance-switching element includes thermal CVD graphitic material; and (f) forming a second conductor above the reversible resistance-switching element.

In a seventh aspect of the invention, a memory cell is provided, the memory cell including: (a) a first conductor; (b) a feature disposed above the first conductor, the feature having a first portion having a first width and a second portion having a second width smaller than the first width; (c) a reversible resistance-switching element disposed on a sidewall of the feature, wherein the reversible resistance-switching element includes thermal CVD graphitic material; and (d) a second conductor disposed above the reversible resistance-switching element.

In an eighth aspect of the invention, a memory cell is provided, the memory cell including: (a) a first conductor; (b) a first insulating material layer disposed above the first conductor, wherein the first insulating material layer has a second width; (c) a second insulating material layer disposed above the first insulating layer, wherein the second insulating material is different from the first insulating material, and wherein the second insulating material layer has a first width; (d) a reversible resistance-switching element disposed on the first insulating material layer and the second insulating material layer, wherein the reversible resistance-switching element includes thermal CVD graphitic material; and (e) a second conductor disposed above the reversible resistance-switching element.

Other features and aspects of the present invention will become more fully apparent from the following detailed description, the appended claims and the accompanying drawings.

### BRIEF DESCRIPTION OF THE DRAWINGS

Features of the present invention can be more clearly understood from the following detailed description considered in conjunction with the following drawings, in which the same reference numerals denote the same elements throughout, and in which:

FIG. 1 is a diagram of an exemplary memory cell in accordance with this invention;

FIG. 2A is a simplified perspective view of an exemplary memory cell in accordance with this invention;

FIG. 2B is a simplified perspective view of a portion of a first exemplary memory level in accordance with this invention;

FIG. 2C is a simplified perspective view of a portion of a first exemplary three-dimensional memory array in accordance with this invention;

FIG. 2D is a simplified perspective view of a portion of a second exemplary three-dimensional memory array in accordance with this invention;

FIG. 3A is a cross-sectional view of an exemplary memory cell in accordance with this invention;

FIG. 3B is a cross-sectional view as indicated by line 3B-3B shown in FIG. 3A;

FIG. 3C is a partial cross-sectional view of the exemplary memory cell of FIG. 3A;

FIG. 3D is a cross-sectional view of another exemplary memory cell in accordance with this invention;

FIG. 3E is a cross-sectional view as indicated by line 3E-3E shown in FIG. 3D;

FIG. 3F is a partial cross-sectional view of the exemplary memory cell of FIG. 3D;

FIGS. 4A-4K illustrate cross-sectional views of a portion of a substrate during an exemplary fabrication of a single memory level in accordance with this invention; and

FIGS. 5A-5L illustrate cross-sectional views of a portion of a substrate during an alternative exemplary fabrication of a single memory level in accordance with this invention.

### DETAILED DESCRIPTION

Carbon films such as graphene, graphite, carbon nano-tubes (collectively referred to herein as “graphitic carbon”), amorphous carbon (“aC”) containing nanocrystalline graphene, amorphous diamond-like carbon (“DLC”), silicon carbide, boron carbide and other similar carbon-based materials may exhibit resistivity-switching behavior that may make such materials suitable for use in microelectronic non-volatile memories.

Indeed, some carbon-based materials have demonstrated reversible resistivity-switching memory properties on lab-scale devices with a 100× separation between ON and OFF states and mid-to-high range resistance changes. Such a separation between ON and OFF states renders carbon-based materials viable candidates for memory cells formed using the carbon materials in memory elements. As used herein, DLC is a carbon material that tends to have primarily tetrahedral carbon-carbon single bonds (often called sp³-bonds), and tends to be amorphous with respect to long range order.

A carbon-based memory element may be formed by arranging a carbon-based resistivity-switching material between bottom and top electrodes to form an MCM device. In such a configuration, the carbon-based resistivity-switching material sandwiched between the two metal or otherwise conducting layers serves as a carbon-based reversible resistance-switching element. A memory cell may then be formed by coupling the MCM device in series with a steering element, such as a diode, tunnel junction, thin film transistor, or the like.

Various methods may be used to form carbon-based resistivity-switching materials for use in an MCM device. One technique, sometimes referred to as “thermal chemical vapor deposition,” or “thermal CVD,” is a method for conformal growth of graphitic carbon. As used herein, “thermal chemical vapor deposition” and “thermal CVD” refer to methods for conformal growth of graphitic carbon at deposition temperatures of between about 700° C.-900° C., more generally between about 600° C.-1000° C. As used herein, graphitic carbon films created using thermal CVD are referred to as “thermal CVD graphitic carbon.”

Although thermal CVD graphitic carbon exhibits resistivity-switching behavior, the switching mechanism differs from that of other carbon films such as amorphous carbon. In particular, researchers have shown that: (1) thermal CVD graphitic carbon switches only after a well-defined crack forms in the carbon material, and switching occurs at the crack site; and (2) crack formation occurs most often at defect sites within the carbon material. Because the location of defect sites in carbon material is generally highly unpredictable, however, it has been difficult to create thermal CVD graphitic carbon memory devices that reliably switch.

In accordance with embodiments of this invention, apparatus and methods are provided for forming thermal CVD graphitic carbon memory cells. In particular, MCM devices are provided that include a reversible resistance-switching element formed from a thermal CVD graphitic material that includes a well-defined highly resistive region that favors crack formation.

In exemplary embodiments of this invention, the thermal CVD graphitic reversible resistance-switching element may be formed including a first portion having a first width, a second portion having a second width smaller than the first width, and a third portion coupled between the first and second portions. The first portion has a first resistance R1, the second portion has a second resistance R2, and the third portion has a third resistance R3, with R3>>R1 and R2. For example, third resistance R3 may be between about 100×-1000×R1, R2.

Although not wanting to be bound by any particular theory, it is believed that the highly resistive third portion includes sp³ defect lines that favor crack formation. As used herein, “sp³ defect lines” are pentagon/heptagon carbon-carbon rings in an sp² hexagon sheet. Accordingly, it is believed that methods in accordance with this invention improve yield and provide uniform switching in thermal CVD graphitic memory devices.

### Exemplary Inventive Memory Cell

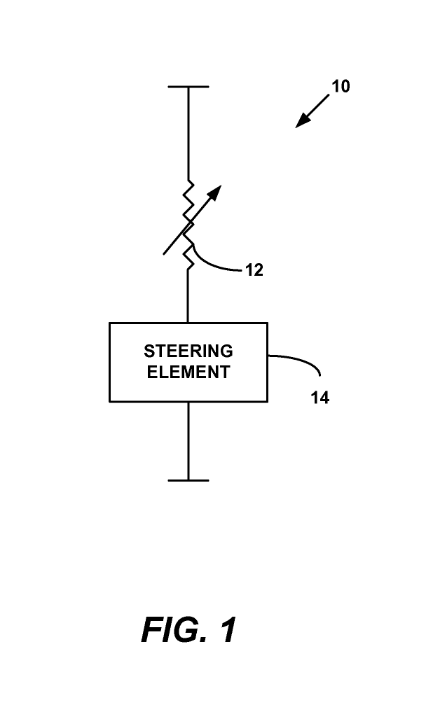

FIG. 1 is a schematic illustration of an exemplary memory cell 10 in accordance with this invention. Memory cell 10 includes a carbon-based reversible resistance-switching element 12 coupled to a steering element 14. Carbon-based reversible resistance-switching element 12 includes a carbon-based reversible resistivity-switching material (not separately shown) having a resistivity that may be reversibly switched between two or more states.

For example, carbon-based reversible resistance-switching material of element 12 may be in an initial, low-resistivity state upon fabrication. Upon application of a first voltage and/or current, the material is switchable to a high-resistivity state. Application of a second voltage and/or current may return reversible resistivity switching material to a low-resistivity state.

When used in a memory cell, one resistance state may represent a binary “0,” whereas another resistance state may represent a binary “1,” although more than two data/resistance states may be used. Numerous reversible resistivity switching materials and operation of memory cells employing reversible resistance switching elements are described, for example, in U.S. patent application Ser. No. 11/125,939, filed May 9, 2005, and titled “Rewriteable Memory Cell Comprising A Diode And A Resistance Switching Material,” (the “'939 Application”) (Docket No. SD-MA-146), which is incorporated by reference herein in its entirety for all purposes.

Steering element 14 may include a thin film transistor, a diode, metal-insulator-metal tunneling current device, or another similar steering element that exhibits non-ohmic conduction by selectively limiting the voltage across and/or the current flow through carbon-based reversible resistance-switching element 12. In this manner, memory cell 10 may be used as part of a two or three dimensional memory array and data may be written to and/or read from memory cell 10 without affecting the state of other memory cells in the array.

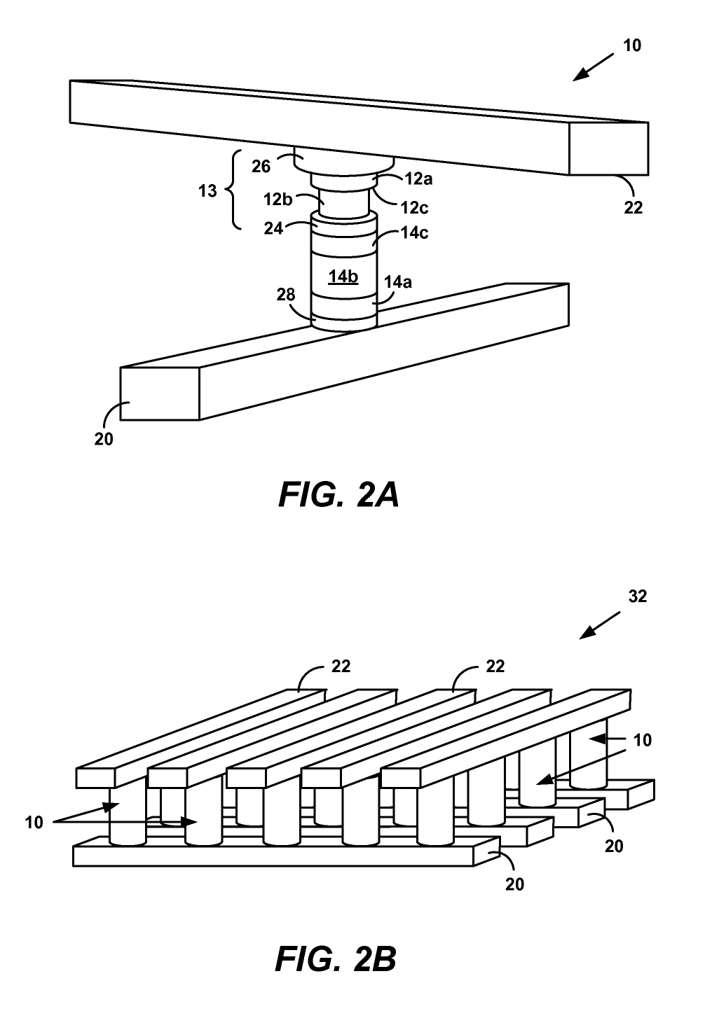

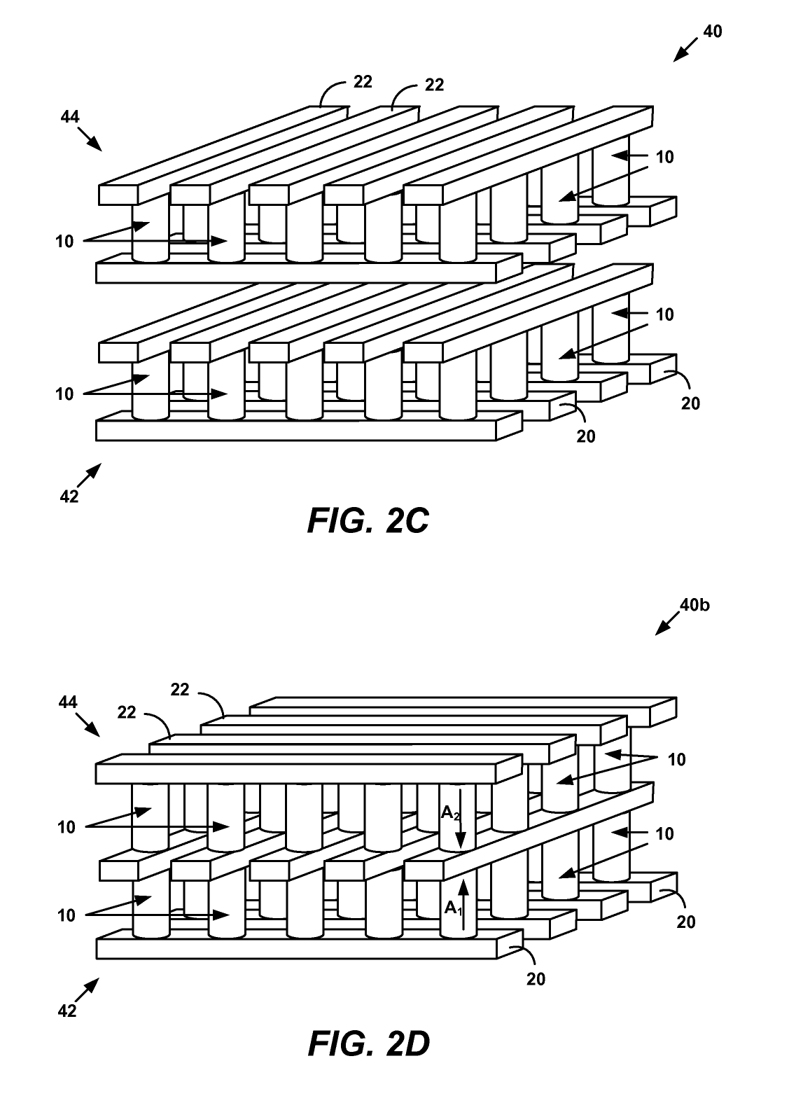

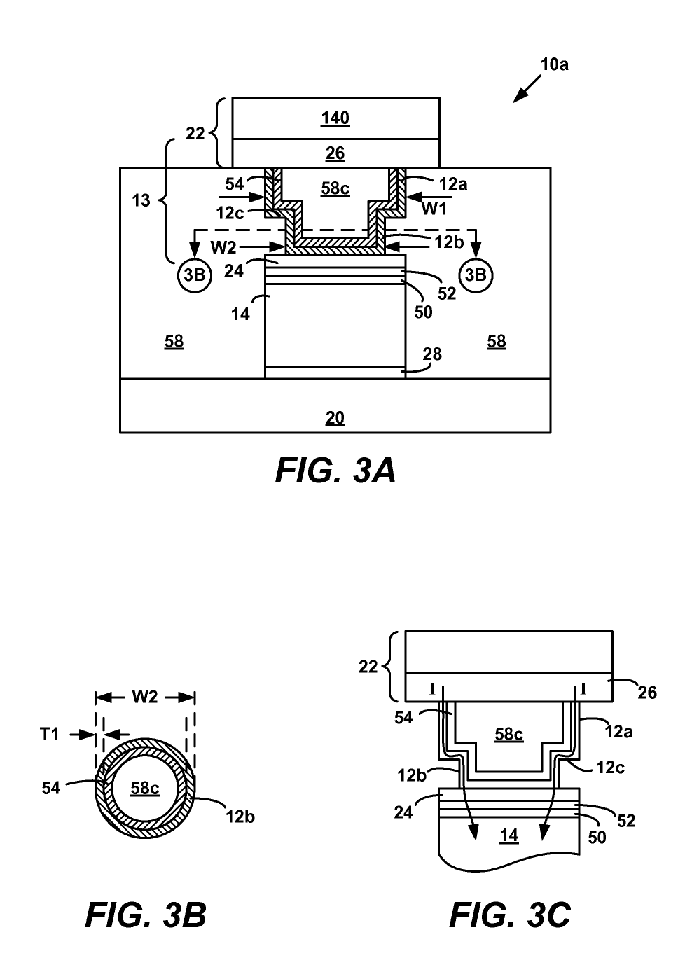

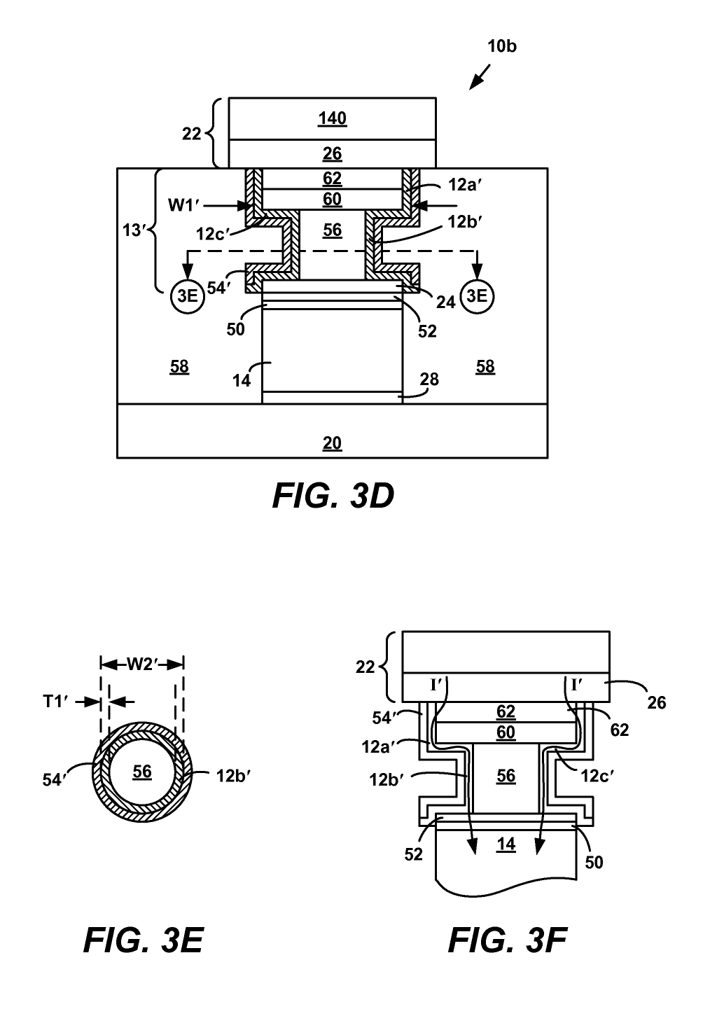

Exemplary embodiments of memory cell 10, carbon-based reversible resistance-switching element 12 and steering element 14 are described below with reference to FIGS. 2A-2D and FIGS. 3A-3F.

### Exemplary Embodiments of Memory Cells and Memory Arrays

FIG. 2A is a simplified perspective view of an exemplary embodiment of a memory cell 10 in accordance with this invention. Memory cell 10 includes a carbon-based reversible resistance-switching element 12 coupled in series with a steering element 14. In some embodiments, carbon-based reversible resistance switching element 12 may be positioned below steering element 14. In some embodiments, steering element 14 may be omitted, and memory cell 10 may be used with a remotely located steering element.

In some embodiments, a barrier layer 24 may be formed between carbon-based reversible resistance switching element 12 and steering element 14, a barrier layer 26 may be formed between carbon-based reversible resistance switching element 12 and second conductor 22, and a barrier layer 28 may be formed between steering element 14 and first conductor 20. Barrier layers 24, 26, and 28 may include titanium nitride, tantalum nitride, tungsten nitride, tungsten, molybdenum, or other similar barrier layer material. In some embodiments, barrier layer 26 may be formed as part of second conductor 22.

Steering element 14 may include a thin film transistor, a diode, a metal-insulator-metal tunneling current device, or another similar steering element that exhibits non-ohmic conduction by selectively limiting the voltage across and/or the current flow through carbon-based reversible resistance switching element 12. In the example of FIG. 2A, steering element 14 is a diode. Accordingly, steering element 14 is sometimes referred to herein as “diode 14.”

Diode 14 may include any suitable diode such as a vertical polycrystalline p-n or p-i-n diode, whether upward pointing with an n-region above a p-region of the diode or downward pointing with a p-region above an n-region of the diode. For example, diode 14 may include a heavily doped n+ polysilicon region 14a, a lightly doped or an intrinsic (unintentionally doped) polysilicon region 14b above the n+ polysilicon region 14a, and a heavily doped p+ polysilicon region 14c above the intrinsic region 14b. It will be understood that the locations of the n+ and p+ regions may be reversed. Exemplary embodiments of diode 14 are described below with reference to FIGS. 3A-3C.

In the exemplary embodiment of FIG. 2A, carbon-based reversible resistance switching element 12 includes a first portion 12a having a first width, a second portion 12b having a second width smaller than the first width, and a third portion 12c coupled between first portion 12a and second portion 12b. In the illustrated embodiment, the first width is substantially the same as the width of diode 14. Persons of ordinary skill in the art will understand that portion 12a alternatively may have a width larger or smaller than the width of diode 14.

In exemplary embodiments of this invention, carbon-based reversible resistance switching element 12 may include conformal graphitic carbon, such as thermal CVD graphitic carbon, or other similar carbon-based reversible resistance-switching material. Barrier layer 24, carbon-based reversible resistance-switching element 12, and barrier layer 26 form an MCM device 13, with barrier layers 24 and 26 forming the bottom and top electrodes, respectively, of MCM device 13.

First conductor 20 and/or second conductor 22 may include any suitable conductive material such as tungsten, any appropriate metal, heavily doped semiconductor material, a conductive silicide, a conductive silicide-germanide, a conductive germanide, or the like. In the embodiment of FIG. 2A, first and second conductors 20 and 22, respectively, are rail-shaped and extend in different directions (e.g., substantially perpendicular to one another). Other conductor shapes and/or configurations may be used. In some embodiments, barrier layers, adhesion layers, antireflection coatings and/or the like (not shown) may be used with the first conductor 20 and/or second conductor 22 to improve device performance and/or aid in device fabrication.

FIG. 2B is a simplified perspective view of a portion of a first memory level 32 formed from a plurality of memory cells 10, such as memory cell 10 of FIG. 2A. For simplicity, reversible resistance switching element 12, steering element 14, and barrier layers 24, 26, and 28 are not separately shown. Memory level 32 is a “cross-point” array including a plurality of bit lines (second conductors 22) and word lines (first conductors 20) to which multiple memory cells are coupled (as shown). Other memory array configurations may be used, as may multiple levels of memory.

For example, FIG. 2C is a simplified perspective view of a portion of a monolithic three dimensional array 40a that includes a first memory level 42 positioned below a second memory level 44. Memory levels 42 and 44 each include a plurality of memory cells 10 in a cross-point array. Persons of ordinary skill in the art will understand that additional layers (e.g., an interlevel dielectric) may be present between the first and second memory levels 42 and 44, but are not shown in FIG. 2C for simplicity. Other memory array configurations may be used, as may additional levels of memory. In the embodiment of FIG. 2C, all diodes may “point” in the same direction, such as upward or downward depending on whether p-i-n diodes having a p-doped region on the bottom or top of the diodes are employed, simplifying diode fabrication.

For example, in some embodiments, the memory levels may be formed as described in U.S. Pat. No. 6,952,030, titled “High-Density Three-Dimensional Memory Cell,” which is hereby incorporated by reference herein in its entirety for all purposes. For instance, the upper conductors of a first memory level may be used as the lower conductors of a second memory level that is positioned above the first memory level as shown in FIG. 2D. In such embodiments, the diodes on adjacent memory levels preferably point in opposite directions as described in U.S. patent application Ser. No. 11/692,151, filed Mar. 27, 2007, and titled “Large Array Of Upward Pointing P-I-N Diodes Having Large And Uniform Current,” (the “'151 Application”) (Docket No. SD-MXA-196X), which is hereby incorporated by reference herein in its entirety for all purposes. For example, as shown in FIG. 2D, the diodes of the first memory level 42 may be upward pointing diodes as indicated by arrow A1 (e.g., with p regions at the bottom of the diodes), whereas the diodes of the second memory level 44 may be downward pointing diodes as indicated by arrow A2 (e.g., with n regions at the bottom of the diodes), or vice versa.

A monolithic three dimensional memory array is one in which multiple memory levels are formed above a single substrate, such as a wafer, with no intervening substrates. The layers forming one memory level are deposited or grown directly over the layers of an existing level or levels. In contrast, stacked memories have been constructed by forming memory levels on separate substrates and adhering the memory levels atop each other, as in Leedy, U.S. Pat. No. 5,915,167, titled “Three Dimensional Structure Memory.” The substrates may be thinned or removed from the memory levels before bonding, but as the memory levels are initially formed over separate substrates, such memories are not true monolithic three dimensional memory arrays.

FIGS. 3A-3C illustrate cross-sectional views of an exemplary embodiment of memory cell 10 of FIG. 2A formed on a substrate, such as a wafer (not shown). With reference to FIG. 3A, memory cell 10a includes a carbon-based reversible resistance switching element 12 coupled in series with diode 14 between first and second conductors 20 and 22, respectively. Memory cell 10a may also include barrier layers 24, 26 and 28, a sidewall liner 54, a silicide layer 50, a silicide-forming metal layer 52, a dielectric layer 58, a dielectric plug 58c, as well as adhesion layers, antireflective coating layers and/or the like (not shown) which may be used with first and/or second conductors 20 and 22, respectively, to improve device performance and/or facilitate device fabrication.

First conductor 20 may include any suitable conductive material such as tungsten, any appropriate metal, heavily doped semiconductor material, a conductive silicide, a conductive silicide-germanide, a conductive germanide, or the like. Second conductor 22 includes a barrier layer 26, which may include titanium nitride or other similar barrier layer material, and conductive layer 140, which may include any suitable conductive material such as tungsten, any appropriate metal, heavily doped semiconductor material, a conductive silicide, a conductive silicide-germanide, a conductive germanide, or the like.

Diode 14 may be a vertical p-n or p-i-n diode, which may either point upward or downward. In the embodiment of FIG. 2D in which adjacent memory levels share conductors, adjacent memory levels preferably have diodes that point in opposite directions such as downward-pointing p-i-n diodes for a first memory level and upward-pointing p-i-n diodes for an adjacent, second memory level (or vice versa).

In some embodiments, diode 14 may be formed from a polycrystalline semiconductor material such as polysilicon, a polycrystalline silicon-germanium alloy, polygermanium or any other suitable material. For example, diode 14 may include a heavily doped n+ polysilicon region 14a, a lightly doped or an intrinsic (unintentionally doped) polysilicon region 14b above the n+ polysilicon region 14a, and a heavily doped p+ polysilicon region 14c above intrinsic region 14b. It will be understood that the locations of the n+ and p+ regions may be reversed.

In some embodiments, a thin germanium and/or silicon-germanium alloy layer (not shown) may be formed on n+ polysilicon region 14a to prevent and/or reduce dopant migration from n+ polysilicon region 14a into intrinsic region 14b. Use of such a layer is described, for example, in U.S. patent application Ser. No. 11/298,331, filed Dec. 9, 2005 and titled “Deposited Semiconductor Structure To Minimize N-Type Dopant Diffusion And Method Of Making” (the “'331 Application”), which is hereby incorporated by reference herein in its entirety for all purposes. In some embodiments, a few hundred angstroms or less of silicon-germanium alloy with about ten atomic percent or more of germanium may be employed.

If diode 14 is fabricated from deposited silicon (e.g., amorphous or polycrystalline), a silicide layer 50 may be formed on diode 14 to place the deposited silicon in a low resistivity state, as fabricated. Such a low resistivity state allows for easier programming of memory cell 10 as a large voltage is not required to switch the deposited silicon to a low resistivity state. For example, a silicide-forming metal layer 52 such as titanium or cobalt may be deposited on p+ polysilicon region 14c. In some embodiments, an additional nitride layer (not shown) may be formed at a top surface of silicide-forming metal layer 52. In particular, for highly reactive metals, such as titanium, an additional cap layer such as TiN layer may be formed on silicide-forming metal layer 52. Thus, in such embodiments, a Ti/TiN stack is formed on top of p+ polysilicon region 14c.

A rapid thermal anneal (“RTA”) step may then be performed to form silicide regions by reaction of silicide-forming metal layer 52 with p+ region 14c. The RTA step may be performed at a temperature between about 650° C. and about 750° C., more generally between about 600° C. and about 800° C., preferably at about 750° C., for a duration between about 10 seconds and about 60 seconds, more generally between about 10 seconds and about 90 seconds, preferably about 1 minute, and causes silicide-forming metal layer 52 and the deposited silicon of diode 14 to interact to form silicide layer 50, consuming all or a portion of the silicide-forming metal layer 52.

As described in U.S. Pat. No. 7,176,064, titled “Memory Cell Comprising A Semiconductor Junction Diode Crystallized Adjacent To A Silicide,” which is incorporated by reference herein in its entirety for all purposes, silicide-forming materials such as titanium and/or cobalt react with deposited silicon during annealing to form a silicide layer. The lattice spacing of titanium silicide and cobalt silicide are close to that of silicon, and it appears that such silicide layers may serve as “crystallization templates” or “seeds” for adjacent deposited silicon as the deposited silicon crystallizes (e.g., silicide layer 50 enhances the crystalline structure of silicon diode 14 during annealing). Lower resistivity silicon thereby is provided. Similar results may be achieved for silicon-germanium alloy and/or germanium diodes.

In embodiments in which a nitride layer was formed at a top surface of silicide-forming metal layer 52, following the RTA step, the nitride layer may be stripped using a wet chemistry. For example, if silicide-forming metal layer 52 includes a TiN top layer, a wet chemistry (e.g., H₂O:H₂O₂:NH₄OH in a 10:2:1 ratio at a temperature of between about 40-60° C.) may be used to strip any residual TiN.

A barrier layer 28, such as TiN, TaN, WN, W, molybdenum, or other similar material, may be formed between first conductor 20 and n+ region 14a (e.g., to prevent and/or reduce migration of metal atoms into the polysilicon regions). In some embodiments, barrier layer 28 may be TiN with a thickness of between about 100 to 2000 angstroms, although other materials and/or thicknesses may be used.

Similarly, a barrier layer 24, such as TiN, TaN, WN, W, molybdenum, or other similar material, may be formed between diode 14 and carbon-based reversible resistance switching element 12. In some embodiments, barrier layer 24 may be TiN with a thickness of between about 100 to 2000 angstroms, although other materials and/or thicknesses may be used.

Second conductor 22 may include a barrier layer 26, such as TiN, TaN, WN, W, molybdenum, or other similar material. In some embodiments, barrier layer 26 may be TiN with a thickness between about 100 to 2000 angstroms, although other materials and/or thicknesses may be used.

In accordance with this invention, carbon-based reversible resistance-switching element 12 and barrier layers 24 and 26 form an MCM device 13 coupled in series with diode 14 between first conductor 20 and second conductor 22, respectively. As illustrated in FIGS. 3A-3B, carbon-based reversible resistance-switching element 12 includes a first portion 12a having a first width W1, a second portion 12b having a second width W2 that is less than first width W1, and a third portion 12c coupled between first portion 12a and second portion 12b.

First portion 12a has a ring-like shape disposed around a first portion of dielectric plug 58c, and second portion 12b has a ring-like shape disposed around a second portion of dielectric plug 58c. Other shapes may be used. First portion 12a has a thickness T1 and first resistance R1, second portion 12b has a thickness T1 and a second resistance R2, and third portion 12c has a third resistance R3, with R3>>R1, R2. For example, third resistance R3 may be between about 100×-1000×R1, R2. In exemplary embodiments, the highly resistive third portion 12c includes sp³ defect lines that favor crack formation.

In this exemplary embodiment, first width W1 is substantially the same as the width of diode 14. First width W1 may be between about 300 angstroms and about 1500 angstroms, more generally between about 200 angstroms and about 5000 angstroms. Persons of ordinary skill in the art will understand, however, that first portion 12a may have a first width W1 larger or smaller than the width of diode 14.

Second width W2 is between about 200 angstroms and about 1400 angstroms, more generally between about 100 angstroms and about 4900 angstroms. For simplicity, the remaining description will refer to carbon-based reversible resistance switching element 12 as “carbon element 12.” Carbon element 12 may be thermal CVD graphitic carbon. Thickness T1 may between about 10 angstroms and about 30 angstroms, more generally between about 7 angstroms and about 100 angstroms.

Table 1 below describes exemplary process conditions for forming thermal CVD graphitic carbon material, which may be used to form carbon element 12.

TABLE 1
EXEMPLARY THERMAL CVD PROCESS
PARAMETERS FOR GRAPHITIC CARBON

| PROCESS PARAMETER | BROAD RANGE | NARROW RANGE |
|---|---|---|
| Precursor “CₓH_{y} + H₂” Flow | 10-5000 | 30-500 |
| Rate (sccm) | | |
| H₂/CₓH_{y} Ratio | 1-10 | 3-5 |
| Chamber Pressure (Torr) | 10-700 | 100-500 |
| Process Temperature (° C.) | 600-1000 | 700-900 |

Exemplary precursors include hydrogen (H₂) and hydrocarbon compounds; hydrocarbon compounds may have the formula CₓH_{y}, with x ranging from about 1 to 4, and y ranging from about 2 to 10. CVD can be done with or without a carrier gas; if a carrier gas is used, the carrier gas may comprise any suitable inert or non-reactive gas such as one or more of He, Ar, H₂, Kr, Xe, N₂, etc. Other precursors, carrier gasses, flow rates, ratios, pressures and/or temperatures may be used.

Memory cell 10A also may include a dielectric sidewall liner 54, which may include silicon nitride (“Si₃N₄”), boron nitride (“BN”), or other similar dielectric material. Sidewall liner 54 may be formed by atomic layer deposition (“ALD”), PECVD, or other similar method and may have a thickness between about 50 angstroms and about 100 angstroms, more generally between about 30 angstroms and about 300 angstroms. Other thicknesses and deposition methods may be used.

Referring again to FIG. 3B, sidewall liner 54 may be formed as a ring, or collar, disposed on a sidewall of carbon element 12, although other shapes may be used. Sidewall liner 54 may protect sidewalls of carbon element 12 during a subsequent deposition of an oxygen-rich dielectric plug 58c. Methods and apparatus for forming dielectric sidewall liners are described, for example, in U.S. patent application Ser. No. 12/536,457, filed Aug. 5, 2009 and titled “A Memory Cell That Includes a Carbon-Based Memory Element and Methods of Forming the Same,” (the “'457 Application”) (Attorney Docket No. SD-MXA-335), which is hereby incorporated by reference in its entirety for all purposes. Dielectric plug 58c may include silicon dioxide, or other similar electrically insulating material.

Although not wanting to be bound by any particular theory, as illustrated in FIG. 3C, it is believed that current I flowing through memory cell 10a flows through second conductor 22, first portion 12a, third portion 12c and second portion 12b of carbon element 12, and through diode 14 to first conductor 20. In addition, it is believed that if R3>>R1, R2, third portion 12c forms a highly resistive region that will favor crack formation when a sufficiently high bias voltage or current (e.g., between about 3-8 volts or between about 0.5-5.0 mA) is applied to memory cell 10a.

Although the exemplary embodiments illustrated in FIG. 3A shows carbon element 12 above diode 14, persons of ordinary skill in the art will understand that carbon element 12 alternatively may be positioned below diode 14. Further, although the exemplary memory cell 10 includes MCM 13 coupled to diode 14, persons of ordinary skill in the art will understand that memory cells 10 in accordance with this invention alternatively may include MCM devices coupled between first and second conductors 20 and 22, respectively, for use with remotely fabricated steering elements.

FIGS. 3D-3F illustrate cross-sectional views of an alternative exemplary embodiment of memory cell 10 of FIG. 2A. With reference to FIG. 3D, memory cell 10b includes a carbon element 12′ coupled in series with diode 14 between first and second conductors 20 and 22, respectively. Memory cell 10b may also include a sidewall liner 54′, a first insulating layer 56, a second insulating layer 60, a barrier layer 62, as well as adhesion layers, antireflective coating layers and/or the like (not shown) which may be used with first and/or second conductors 20 and 22, respectively, to improve device performance and/or facilitate device fabrication.

First insulating layer 56 is fabricated from a different material than second insulating layer 60. The materials used to form first insulating layer 56 and second insulating layer 60 preferably are easy to etch, and have good etch selectivity between one another, and between each insulating material and dielectric materials, such as silicon dioxide. For example, silicon, silicon nitride, silicon oxide, alumina, other similar oxide/nitride, or other similar materials may be used to form first insulating layer 56 and second insulating layer 60.

In some embodiments, first insulating layer 56 includes approximately 200 to 500 angstroms, more generally 100 to 1000 angstroms of silicon nitride, and second insulating layer 60 includes approximately 200 to 500 angstroms, more generally 100 to 1000 angstroms of hafnium dioxide. Other insulating materials and/or thicknesses may be used.

Barrier layer 62 may include TiN, TaN, W, WN, molybdenum, or other similar material. In some embodiments, barrier layer 62 may be TiN with a thickness between about 500-1000 angstroms, although other materials and/or thicknesses may be used.

In accordance with this invention, carbon element 12′ and barrier layers 24 and 62 form an MCM device coupled in series with diode 14 between first and second conductors 20 and 22, respectively. As illustrated in FIGS. 3D-3E, carbon element 12′ includes a first portion 12a′ having a first width W1′, a second portion 12b′ having a second width W2′ that is less than first width W1′, and a third portion 12c′ coupled between first portion 12a′ and second portion 12b′. First portion 12a′ has a ring-like shape disposed around second insulating layer 60 and barrier layer 62, and second portion 12b′ has a ring-like shape disposed around first insulating layer 56. Other shapes may be used. First portion 12a′ has a thickness T1′ and first resistance R1′, second portion 12b′ has a thickness T1′ and a second resistance R2′, and third portion 12c′ has a third resistance R3′, with R3′>>R1′, R2′. For example, third resistance R3′ may be between about 100×-1000×R1′, R2′. In exemplary embodiments, the highly resistive third portion 12c′ includes sp³ defect lines that favor crack formation.

In this exemplary embodiment, first width W1′ is greater than the width of diode 14. First width W1′ may be between about 320 angstroms and about 1560 angstroms, more generally between about 220 angstroms and about 5060 angstroms.

Second width W2′ is between about 220 angstroms and about 1460 angstroms, more generally between about 120 angstroms and about 4960 angstroms. Carbon element 12′ may be thermal CVD graphitic carbon formed such as described above in connection with Table 1, and may have a thickness T1′ between about 10 angstroms and about 30 angstroms, more generally between about 7 angstroms and about 100 angstroms.

Memory cell 10b also may include a dielectric sidewall liner 54′, which may include Si₃N₄, BN, or other similar dielectric material. Sidewall liner 54′ may be formed by ALD, PECVD, or other similar method and may have a thickness between about 50 angstroms and about 100 angstroms, more generally between about 30 angstroms and about 300 angstroms. Other thicknesses and deposition methods may be used.

Sidewall liner 54′ may be formed as a ring, or collar, disposed on a sidewall of carbon element 12′, although other shapes may be used. Sidewall liner 54′ may protect sidewalls of carbon element 12 during a subsequent deposition of an oxygen-rich dielectric 58.

Although not wanting to be bound by any particular theory, as illustrated in FIG. 3F, it is believed that current I′ flowing through memory cell 10b flows through second conductor 22, barrier layer 62, first portion 12a′, third portion 12c′ and second portion 12b′ of carbon element 12′, and through diode 14 to first conductor 20. In addition, it is believed that if R3′>>R1′, R2′, third portion 12c′ forms a highly resistive region that will favor crack formation when a sufficiently high bias voltage or current is applied to memory cell 10b.

Although the exemplary embodiments illustrated in FIG. 3D shows carbon element 12′ above diode 14, persons of ordinary skill in the art will understand that carbon element 12′ alternatively may be positioned below diode 14. Further, although the exemplary memory cell 10b includes MCM 13′ coupled to diode 14, persons of ordinary skill in the art will understand that memory cells 10b in accordance with this invention alternatively may include MCM devices coupled between first and second conductors 20 and 22, respectively, for use with remotely fabricated steering elements.

### Exemplary Fabrication Processes for Memory Cells

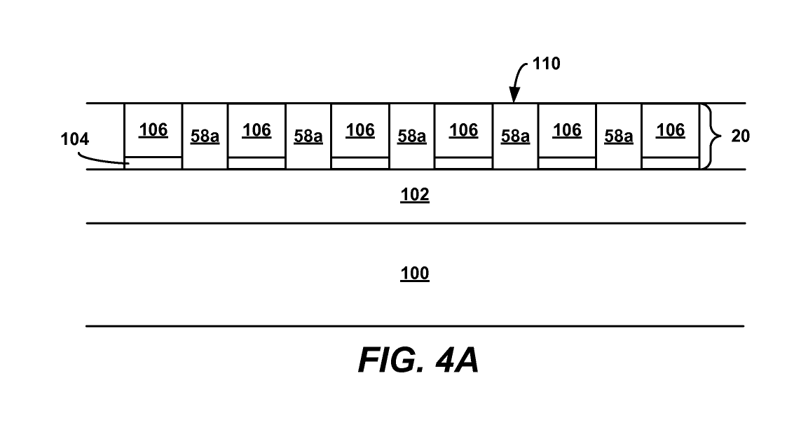

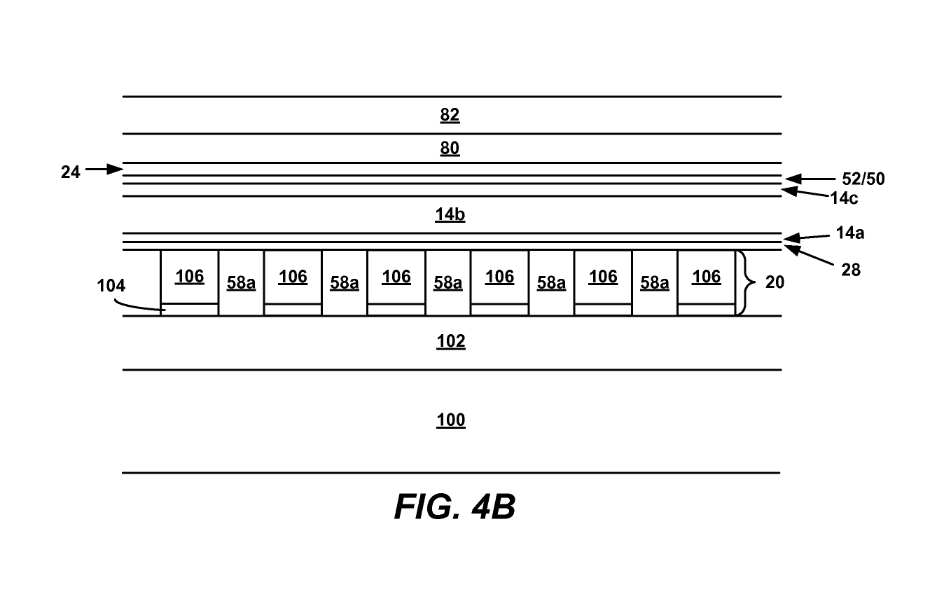

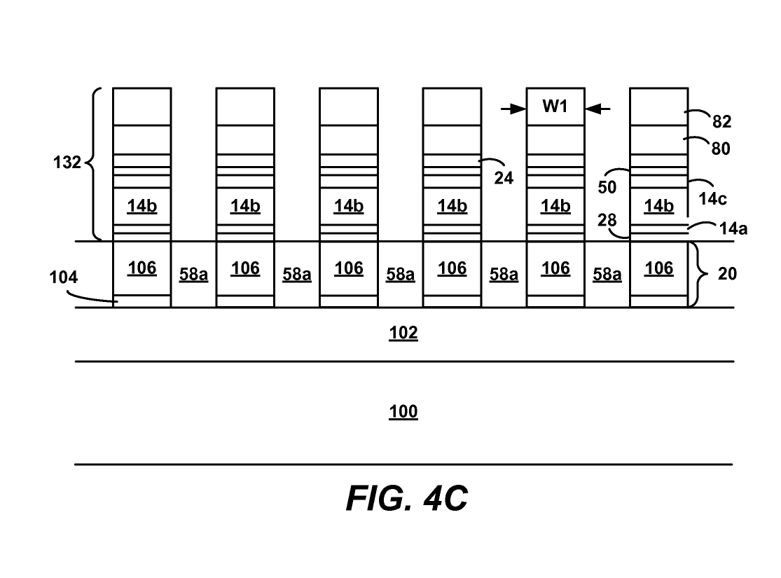

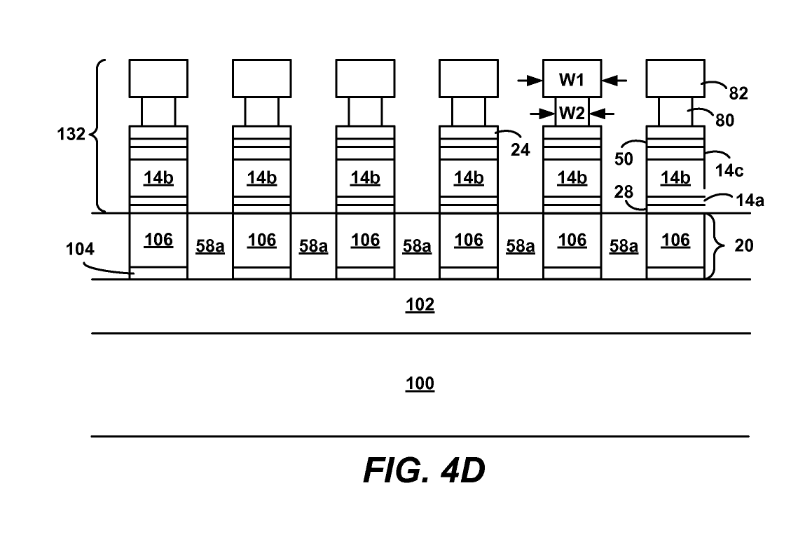

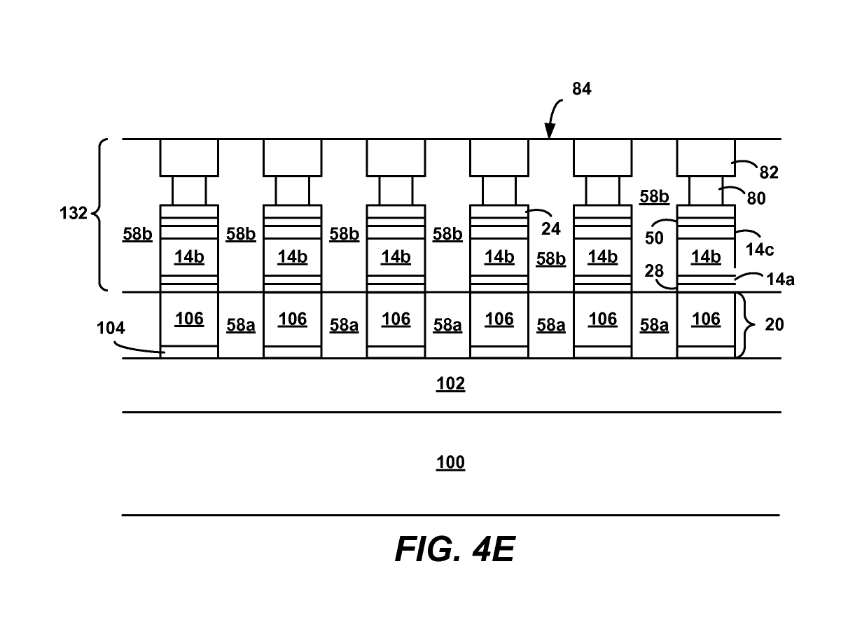

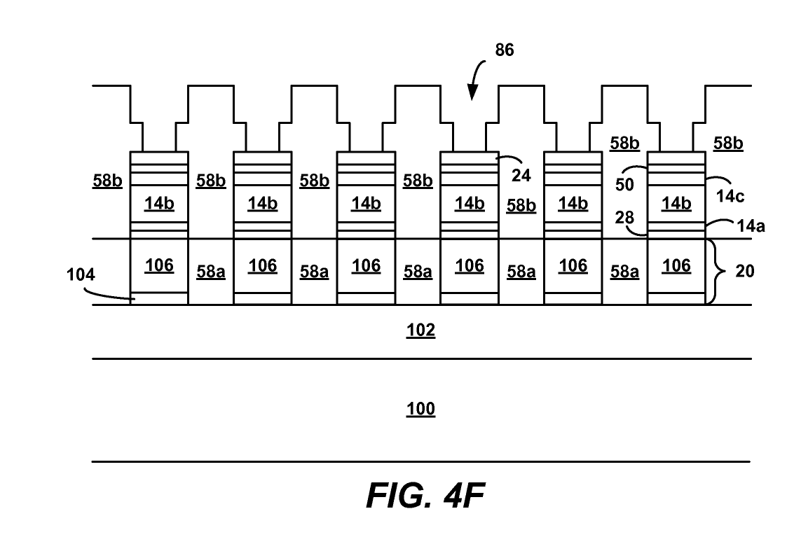

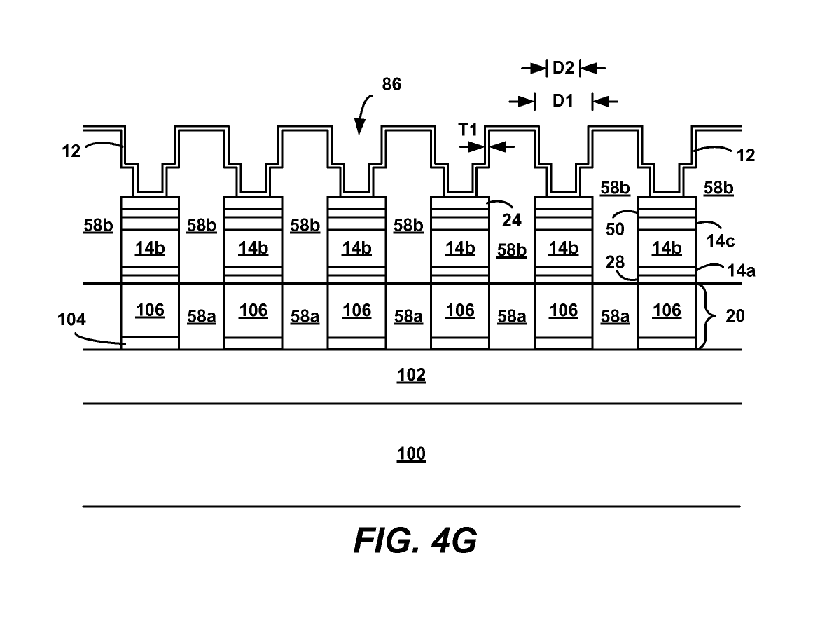

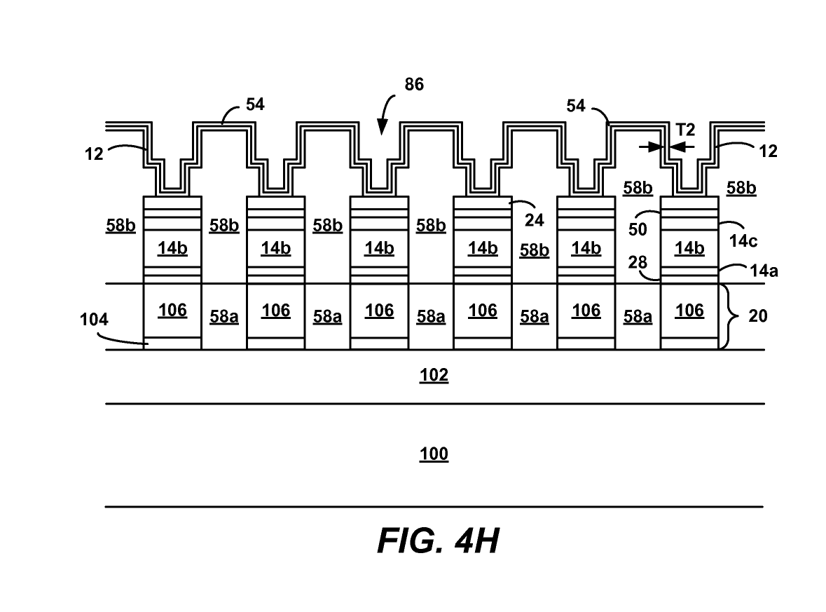

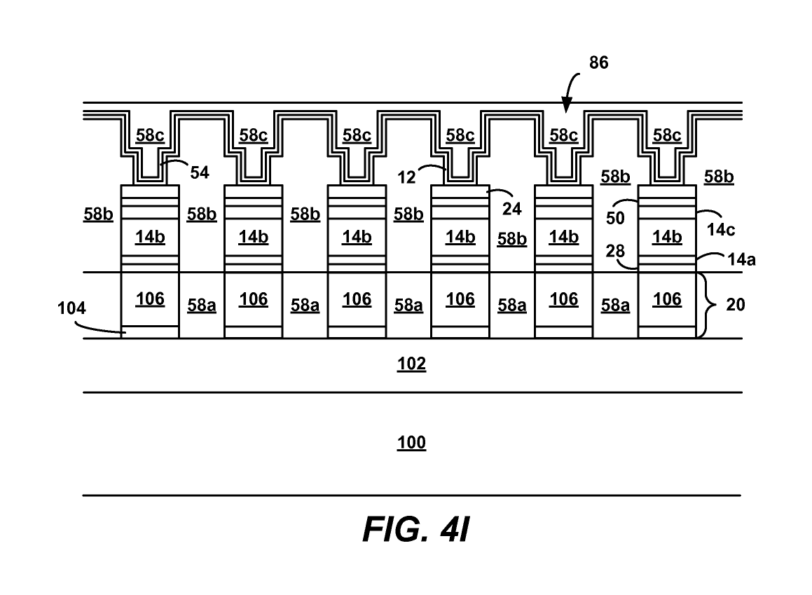

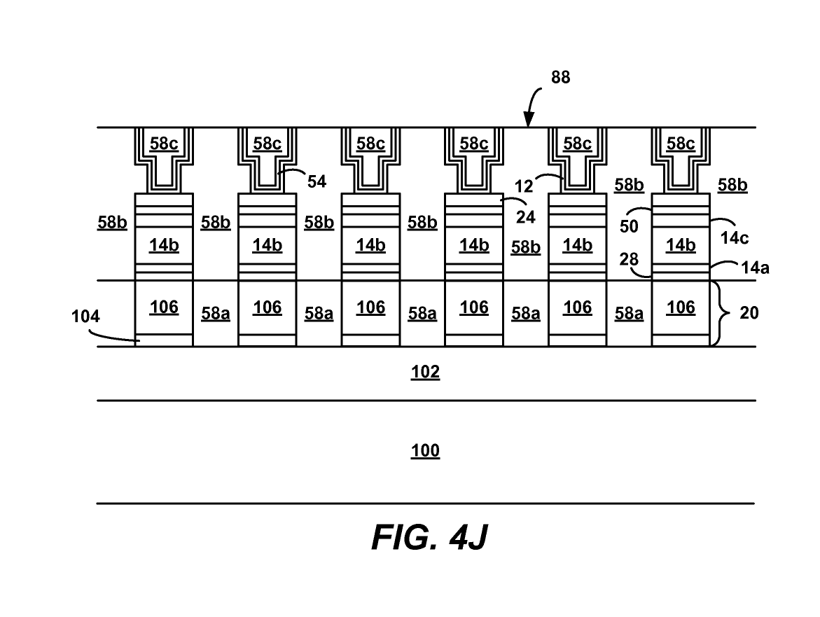

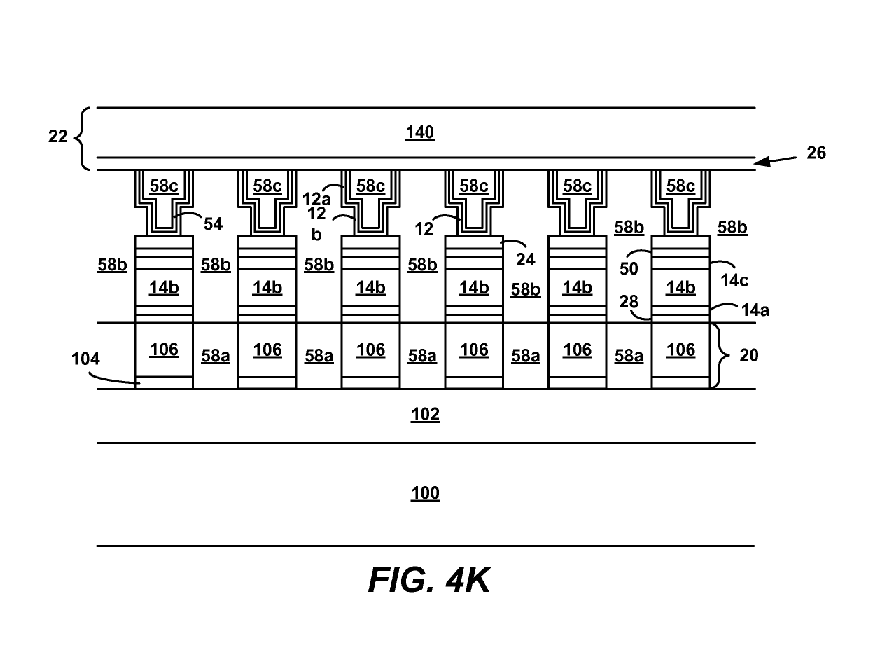

Referring now to FIGS. 4A-4K, a first exemplary method of forming an exemplary memory level in accordance with this invention is described. As will be described below, the first memory level includes a plurality of memory cells that each include a steering element and a reversible resistance switching element coupled to the steering element. Additional memory levels may be fabricated above the first memory level (as described previously with reference to FIGS. 2C-2D).

With reference to FIG. 4A, substrate 100 is shown as having already undergone several processing steps. Substrate 100 may be any suitable substrate such as a silicon, germanium, silicon-germanium, undoped, doped, bulk, silicon-on-insulator (“SOI”) or other substrate with or without additional circuitry. For example, substrate 100 may include one or more n-well or p-well regions (not shown).

Isolation layer 102 is formed above substrate 100. In some embodiments, isolation layer 102 may be a layer of silicon dioxide, silicon nitride, silicon oxynitride or any other suitable insulating layer.

Following formation of isolation layer 102, an adhesion layer 104 is formed over isolation layer 102 (e.g., by physical vapor deposition or another method). For example, adhesion layer 104 may be between about 20 to about 500 angstroms, and preferably about 100 angstroms, of titanium nitride or another suitable adhesion layer such as tantalum nitride, tungsten nitride, combinations of one or more adhesion layers, or the like. Other adhesion layer materials and/or thicknesses may be employed. In some embodiments, adhesion layer 104 may be optional.

After formation of adhesion layer 104, a conductive layer 106 is deposited over adhesion layer 104. Conductive layer 106 may include any suitable conductive material such as tungsten or another appropriate metal, heavily doped semiconductor material, a conductive silicide, a conductive silicide-germanide, a conductive germanide, or the like deposited by any suitable method (e.g., chemical vapor deposition (“CVD”), PVD, etc.). In at least one embodiment, conductive layer 106 may comprise between about 200 angstroms to about 2500 angstroms of tungsten. Other conductive layer materials and/or thicknesses may be used.

Following formation of conductive layer 106, adhesion layer 104 and conductive layer 106 are patterned and etched. For example, adhesion layer 104 and conductive layer 106 may be patterned and etched using conventional lithography techniques, with a soft or hard mask, and wet or dry etch processing. In at least one embodiment, adhesion layer 104 and conductive layer 106 are patterned and etched to form substantially parallel, substantially co-planar first conductors 20. Exemplary widths for first conductors 20 and/or spacings between first conductors 20 are between about 200 angstroms and about 2500 angstroms, although other conductor widths and/or spacings may be used.

After first conductors 20 have been formed, a dielectric layer 58a is formed over substrate 100 to fill the voids between first conductors 20. For example, approximately 3000-7000 angstroms of silicon dioxide may be deposited on the substrate 100 and planarized using chemical mechanical polishing or an etchback process to form a planar surface 110. Planar surface 110 includes exposed top surfaces of first conductors 20 separated by dielectric material (as shown). Other dielectric materials such as silicon nitride, silicon oxynitride, low k dielectrics, etc., and/or other dielectric layer thicknesses may be used. Exemplary low k dielectrics include carbon doped oxides, silicon carbon layers, or the like.

In other embodiments of the invention, first conductors 20 may be formed using a damascene process in which dielectric layer 58a is formed, patterned and etched to create openings or voids for first conductors 20. The openings or voids then may be filled with adhesion layer 104 and conductive layer 106 (and/or a conductive seed, conductive fill and/or barrier layer if needed). Adhesion layer 104 and conductive layer 106 then may be planarized to form planar surface 110. In such an embodiment, adhesion layer 104 will line the bottom and sidewalls of each opening or void.

Following planarization, the diode structures of each memory cell are formed. With reference to FIG. 4B, a barrier layer 28 is formed over planarized top surface 110 of substrate 100. Barrier layer 28 may be between about 20 angstroms and about 500 angstroms, and preferably about 100 angstroms, of titanium nitride or another suitable barrier layer such as tantalum nitride, tungsten nitride, tungsten, molybdenum, combinations of one or more barrier layers, barrier layers in combination with other layers such as titanium/titanium nitride, tantalum/tantalum nitride or tungsten/tungsten nitride stacks, or the like. Other barrier layer materials and/or thicknesses may be employed.

After deposition of barrier layer 28, deposition of the semiconductor material used to form the diode of each memory cell begins (e.g., diode 14 in FIGS. 2 and 3). Each diode may be a vertical p-n or p-i-n diode as previously described. In some embodiments, each diode is formed from a polycrystalline semiconductor material such as polysilicon, a polycrystalline silicon-germanium alloy, polygermanium or any other suitable material. For convenience, formation of a polysilicon, downward-pointing diode is described herein. It will be understood that other materials and/or diode configurations may be used.

With reference to FIG. 4B, following formation of barrier layer 28, a heavily doped n+ silicon layer 14a is deposited on barrier layer 28. In some embodiments, n+ silicon layer 14a is in an amorphous state as deposited. In other embodiments, n+ silicon layer 14a is in a polycrystalline state as deposited. CVD or another suitable process may be employed to deposit n+ silicon layer 14a. In at least one embodiment, n+ silicon layer 14a may be formed, for example, from about 100 angstroms to about 1000 angstroms, preferably about 100 angstroms, of phosphorus or arsenic doped silicon having a doping concentration of about 1×10²¹ cm⁻³. Other layer thicknesses, doping types and/or doping concentrations may be used. N+ silicon layer 14a may be doped in situ, for example, by flowing a donor gas during deposition. Other doping methods may be used (e.g., implantation).

After deposition of n+ silicon layer 14a, a lightly doped, intrinsic and/or unintentionally doped silicon layer 14b is formed over n+ silicon layer 14a. In some embodiments, intrinsic silicon layer 14b is in an amorphous state as deposited. In other embodiments, intrinsic silicon layer 14b is in a polycrystalline state as deposited. CVD or another suitable deposition method may be employed to deposit intrinsic silicon layer 14b. In at least one embodiment, intrinsic silicon layer 14b may be about 500 angstroms to about 4800 angstroms, preferably about 2500 angstroms, in thickness. Other intrinsic layer thicknesses may be used.

A thin (e.g., a few hundred angstroms or less) germanium and/or silicon-germanium alloy layer (not shown) may be formed on n+ silicon layer 14a prior to depositing intrinsic silicon layer 14b to prevent and/or reduce dopant migration from n+ silicon layer 14a into intrinsic silicon layer 14b (as described in the '331 Application, previously incorporated).

Heavily doped, p-type silicon is either deposited and doped by ion implantation or is doped in situ during deposition to form a p+ silicon layer 14c. For example, a blanket p+ implant may be employed to implant boron a predetermined depth within intrinsic silicon layer 14b. Exemplary implantable molecular ions include BF₂, BF₃, B, Ga, Al and the like. In some embodiments, an implant dose of about 1-5×10¹⁵ ions/cm² may be employed. Other implant species and/or doses may be used. Further, in some embodiments, a diffusion process may be employed. In at least one embodiment, the resultant p+ silicon layer 14c has a thickness of between about 100 angstroms and about 700 angstroms, although other p+ silicon layer sizes may be used.

Following formation of p+ silicon layer 14c, a silicide-forming metal layer 52 is deposited over p+silicon layer 14c. Exemplary silicide-forming metals include sputter or otherwise deposited titanium or cobalt. In some embodiments, silicide-forming metal layer 52 has a thickness of between about 10 angstroms and about 200 angstroms, preferably between about 20 angstroms and about 50 angstroms and more preferably about 20 angstroms. Other silicide-forming metal layer materials and/or thicknesses may be used. A nitride layer (not shown) may be formed at the top of silicide-forming metal layer 52.

Following formation of silicide-forming metal layer 52, an RTA step may be performed at about 540° C. for about one minute to form silicide layer 50, consuming all or a portion of the silicide-forming metal layer 52. Following the RTA step, any residual nitride layer from silicide-forming metal layer 52 may be stripped using a wet chemistry, as described above, and as is known in the art.

A barrier layer 24 is deposited over silicide-forming metal layer 52. Barrier layer 24 may be between about 20 angstroms and about 500 angstroms, and more preferably about 200 angstroms, of titanium nitride or another suitable barrier layer such as tantalum nitride, tungsten nitride, tungsten, molybdenum, combinations of one or more barrier layers, barrier layers in combination with other layers such as titanium/titanium nitride, tantalum/tantalum nitride or tungsten/tungsten nitride stacks, or the like. Other barrier layer materials and/or thicknesses may be employed. Any suitable method may be used to form barrier layer 56. For example, PVD, ALD, or the like may be employed.

Next, a first layer 80 is deposited over barrier layer 24, and second layer 82 is deposited over first layer 80. As will be described below, layers 80 and 82 will be used in a Damascene process to form voids that will be filled with reversible resistance-switching material. In this regard, layers 80 and 82 are sometimes called “sacrificial layers.”

First sacrificial layer 80 is fabricated from a different material than second sacrificial layer 82. The materials used to form first sacrificial layer 80 and second sacrificial layer 82 preferably are easy to etch, and have good etch selectivity between one another, and between each sacrificial material and dielectric materials, such as silicon dioxide. For example, silicon, germanium, carbon, or other similar materials may be used to form first sacrificial layer 80 and second sacrificial layer 82.

In at least one embodiment, first sacrificial layer 80 includes approximately 200 to 500 angstroms, more generally 100 to 1000 angstroms of carbon, and second sacrificial layer 82 includes approximately 200 to 500 angstroms, more generally 100 to 1000 angstroms of germanium. Other sacrificial materials and/or thicknesses may be used. Any suitable method may be used to form first sacrificial layer 80 and second sacrificial layer 82. For example, CVD, PVD, ALD, or the like may be employed.

As shown in FIG. 4C, second sacrificial layer 82, first sacrificial layer 80, barrier layer 24, silicide layer 50, diode layers 14a-14c and barrier layer 28 are patterned and etched to form pillars 132 having a first width W1. For example, pillars 132 may have a first width W1 between about 300 angstroms and about 1500 angstroms, more generally between about 200 angstroms and 5000 angstroms. Pillars 132 may have about the same pitch and about the same width W1 as conductors 20 below, such that each pillar 132 is formed on top of a conductor 20. Some misalignment may be tolerated.

For example, photoresist may be deposited, patterned using standard photolithography techniques, layers 82, 80, 24, 50, 14a-14c, and 28 may be etched, and then the photoresist may be removed. Alternatively, a hard mask of some other material, for example silicon dioxide, may be formed on top of the barrier layer 82, with bottom antireflective coating (“BARC”) on top, then patterned and etched. Similarly, dielectric antireflective coating (“DARC”) may be used as a hard mask.

Pillars 132 may be formed using any suitable masking and etching process. For example, layers 82, 80, 24, 50, 14a-14c, and 28 may be patterned with about 1 micron to about 1.5 micron, more preferably about 1.2 micron to about 1.4 micron, of photoresist (“PR”) using standard photolithographic techniques. Thinner PR layers may be used with smaller critical dimensions and technology nodes. In some embodiments, an oxide hard mask may be used below the PR layer to improve pattern transfer and protect underlying layers during etching.

Any suitable etch chemistries, and any suitable etch parameters, flow rates, chamber pressures, power levels, process temperatures, and/or etch rates may be used.

After etching, pillars 132 may be cleaned using a dilute hydrofluoric/sulfuric acid clean. Such cleaning, whether or not PR asking is performed before etching, may be performed in any suitable cleaning tool, such as a Raider tool, available from Semitool of Kalispell, Mont. Exemplary post-etch cleaning may include using ultra-dilute sulfuric acid (e.g., about 1.5-1.8 wt %) for about 60 seconds and ultra-dilute hydrofluoric (“HF”) acid (e.g., about 0.4-0.6 wt) for 60 seconds. Megasonics may or may not be used.

As shown in FIG. 4D, first sacrificial regions 80 are narrowed using a shrink technique to form first sacrificial regions 80 having a second width W2. In some embodiments, shrunken first sacrificial regions 80 have a second width W2 between about 200 angstroms and about 1400 angstroms, more generally between about 100 angstroms and about 4900 angstroms. Persons of ordinary skill in the art will understand that other second width W2 values may be used.

Preferably, shrink techniques are employed that selectively reduce the width of only first sacrificial regions 80 and preferably do not affect other layers of pillar 132. Shrinking the width of first sacrificial layer 80 may be accomplished, for example, by laterally etching them.

For example, if first sacrificial regions 80 comprise carbon, any suitable carbon layer shrink technique may be used, such as one based on a selective wet etch chemistry, dry etch chemistry, or energetic plasma species. For instance, energetic plasma species of oxygen, hydrogen, and/or amine (NH₂) may be formed using appropriate precursor gases (e.g., O₂, NH₃, H₂, N₂O, CO, CO₂, etc.) and used to selectively thin the width of first sacrificial regions 80. The amount of undercut of first sacrificial regions 80 may be controlled, for instance, by controlling the degree of plasma non directionality, which itself may be controlled, for example, by modulating pressure, plasma density, percentage of ions, and ion energy. Non-directionality control appears to improve when using in-situ RF plasma, as compared to using a remote plasma source.

Next, a dielectric layer 58b may be deposited over pillars 132 to fill the voids between pillars 132. For example, approximately 2000-7000 angstroms of silicon dioxide may be deposited and planarized using chemical mechanical polishing or an etchback process to remove excess dielectric material 58b and form a planar surface 84, resulting in the structure illustrated in FIG. 4E. Planar surface 84 includes exposed top surfaces of pillars 132 separated by dielectric material 58b (as shown). Other dielectric materials such as silicon nitride, silicon oxynitride, low k dielectrics, etc., and/or other dielectric layer thicknesses may be used. Exemplary low k dielectrics include carbon doped oxides, silicon carbon layers, or the like.

Next, first sacrificial regions 80 and second sacrificial regions 82 are removed, such as by a selective wet or dry etch process, to form voids 86, resulting in the structure shown in FIG. 4F. For example, carbon and germanium may be selectively etched relative to silicon dioxide using any dry etching technique.

Next, a layer 12 of carbon material may be conformally deposited in voids 86, resulting in the structure shown in FIG. 4G. For example, carbon layer 12 may be formed by using thermal CVD graphitic carbon to conformally deposit between about 10 angstroms and about 30 angstroms, more generally between about 7 angstroms and about 100 angstroms of thermal CVD graphitic carbon. Exemplary process parameters for forming thermal CVD graphitic carbon are described in Table 1 above. Persons of ordinary skill in the art will understand that other carbon-based materials, deposition methods and/or thicknesses may be used.

As illustrated in FIG. 4G, carbon layer 12 has a vertical sidewall thickness T1. In some embodiments, carbon layer 12 has a vertical sidewall thickness T1 of between about 7 angstroms and about 100 angstroms, and more preferably between about 10 angstroms and about 30 angstroms. Other thicknesses may be used.

As illustrated in FIG. 4H, a conformal dielectric layer 54 is deposited above carbon layer 12. Dielectric layer 54 may be formed using silicon nitride, silicon oxynitride, boron nitride, low k dielectrics, or other similar dielectric material. Exemplary low k dielectrics include carbon doped oxides, silicon carbon layers, or the like. Dielectric layer 54 has a vertical sidewall thickness T2. In some embodiments, dielectric layer 54 has a vertical sidewall thickness T2 between about 50 angstroms and about 100 angstroms, more generally between about 30 angstroms and about 300 angstroms. Other thicknesses may be used. Any suitable method may be used to form layer 54. For example, PECVD, ALD, or the like may be employed.

With reference to FIG. 4I, a dielectric layer 58c is deposited over substrate 100 to fill voids 86. For example, approximately 1500 to about 3500 angstroms of silicon dioxide may be deposited. Other dielectric materials such as silicon nitride, silicon oxynitride, low k dielectrics, etc., and/or other dielectric layer thicknesses may be used. Exemplary low k dielectrics include carbon doped oxides, silicon carbon layers, or the like. The structure is planarized using chemical mechanical polishing or an etchback process to remove excess dielectric material 58c and form a planar surface 88, resulting in the structure illustrated in FIG. 4J. Planarization may remove portions of dielectric sidewall liner 54 and carbon element 12. Accordingly, planar surface 88 includes exposed top surfaces of dielectric sidewall liner 54 and carbon element 12 separated by dielectric material 58c (as shown).

With reference to FIG. 4K, following planarization of dielectric layer 58c, a second conductor 22 is formed in a manner similar to the formation of first conductors 20. For example, in some embodiments, one or more barrier layers and/or adhesion layers 26 may be deposited prior to deposition of a conductive layer 140 used to form the second conductor 22.

Conductive layer 140 may be formed from any suitable conductive material such as tungsten, another suitable metal, heavily doped semiconductor material, a conductive silicide, a conductive silicide-germanide, a conductive germanide, or the like deposited by any suitable method (e.g., CVD, PVD, etc.). Barrier layers and/or adhesion layers 26 may include titanium nitride or another suitable layer such as tantalum nitride, tungsten nitride, combinations of one or more layers, or any other suitable material(s). In at least one embodiment, conductive layer 140 may comprise about 200 to about 2500 angstroms of tungsten, and barrier/adhesion layer 26 may comprise about 20 to about 500 angstroms of TiN. Other conductive layer and barrier layer materials and/or thicknesses may be used.

The deposited conductive layer 140 and barrier and/or adhesion layer 26, may be patterned and etched to form second conductors 22. In at least one embodiment, second conductors 22 are substantially parallel, substantially coplanar conductors that extend in a different direction than first conductors 20.

In other embodiments of the invention, second conductors 22 may be formed using a damascene process in which a dielectric layer is formed, patterned and etched to create openings or voids for conductors 22. The openings or voids may be filled with adhesion layer 26 and conductive layer 140 (and/or a conductive seed, conductive fill and/or barrier layer if needed). Adhesion layer 26 and conductive layer 140 then may be planarized to form a planar surface.

Following formation of second conductors 22, the resultant structure may be annealed to crystallize the deposited semiconductor material of diodes 14 (and/or to form silicide regions by reaction of the silicide-forming metal layer 52 with p+ region 14c). In at least one embodiment, the anneal may be performed for about 10 seconds to about 2 minutes in nitrogen at a temperature of about 600° C. to 800° C., and more preferably between about 650° C. and 750° C. Other annealing times, temperatures and/or environments may be used. The silicide regions formed as each silicide-forming metal layer region 52 and p+ region 14c react may serve as “crystallization templates” or “seeds” during annealing for underlying deposited semiconductor material that forms diodes 14 (e.g., changing any amorphous semiconductor material to polycrystalline semiconductor material and/or improving overall crystalline properties of diodes 14). Lower resistivity diode material thereby is provided.

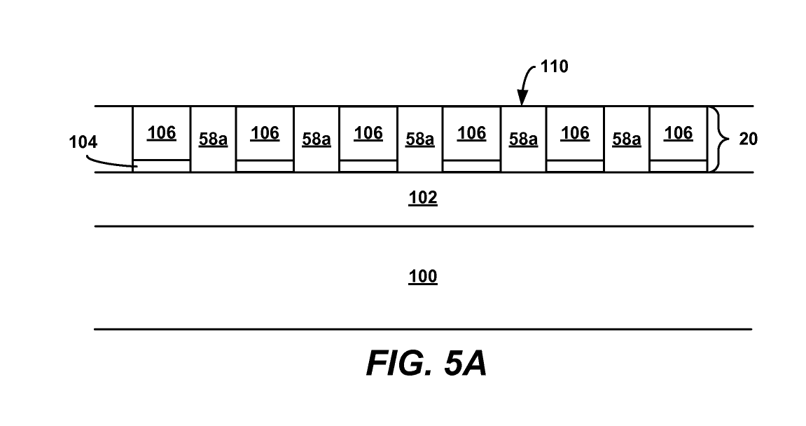

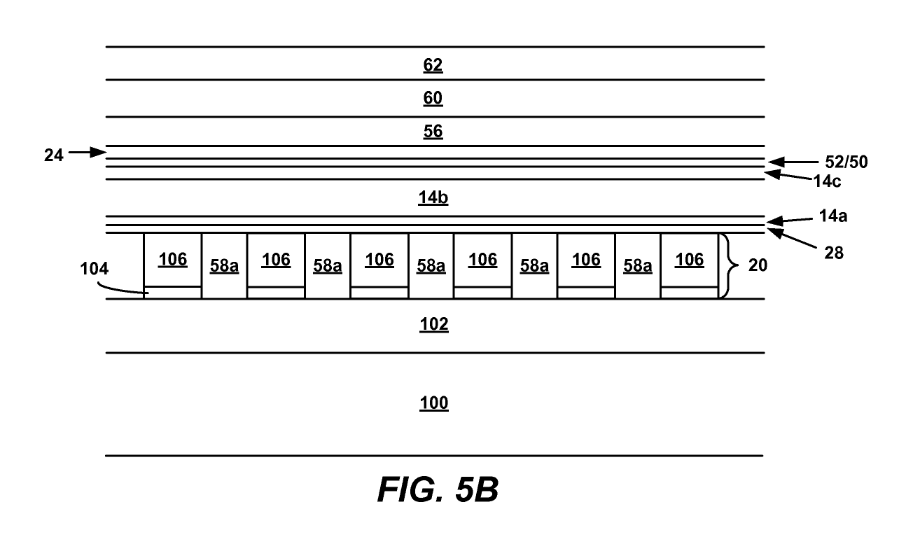

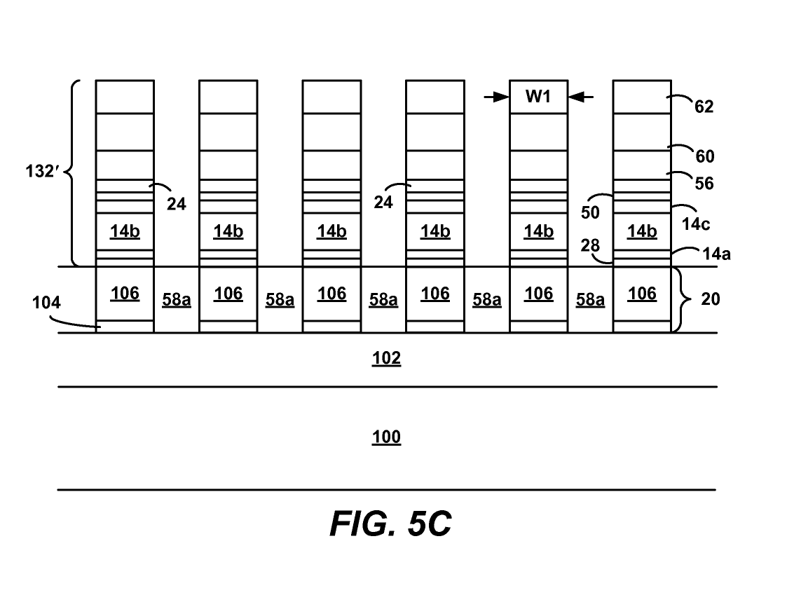

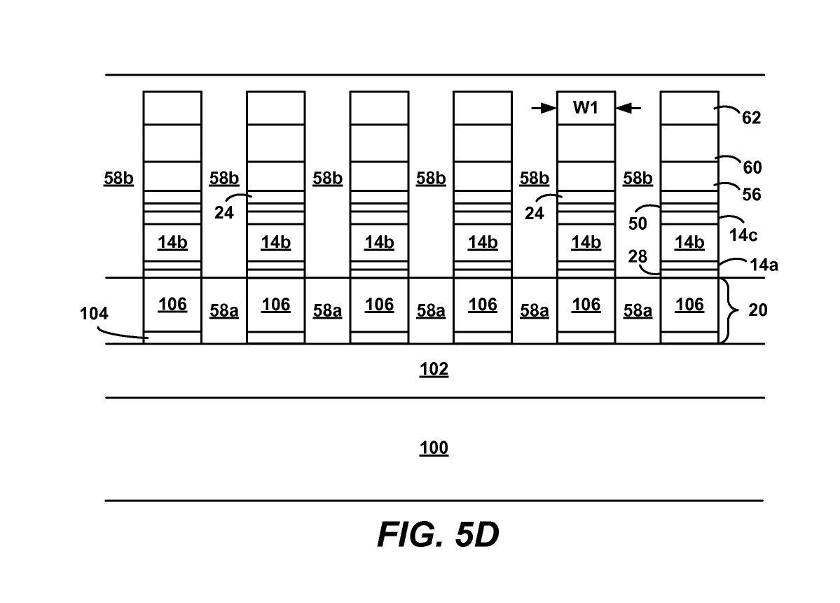

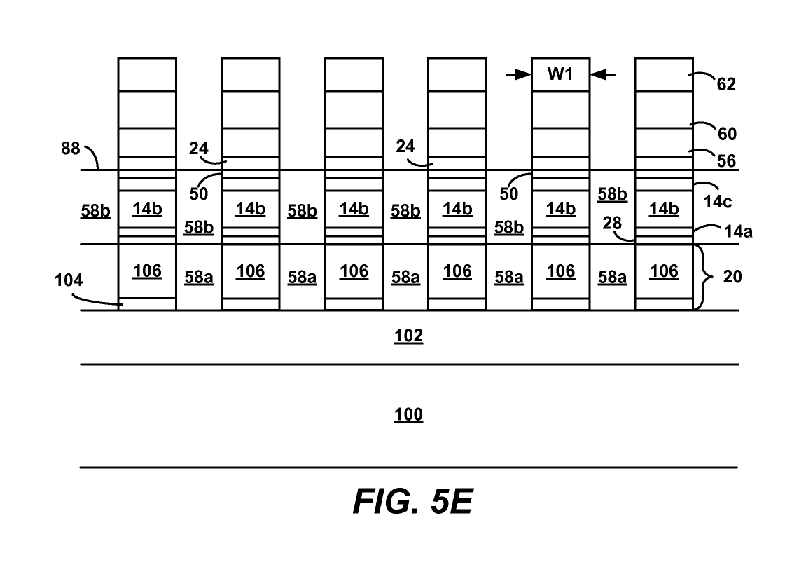

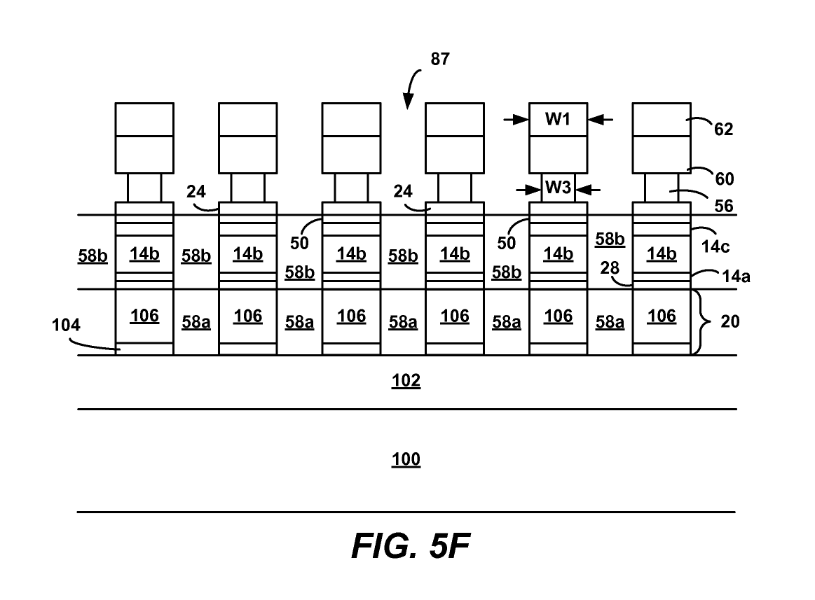

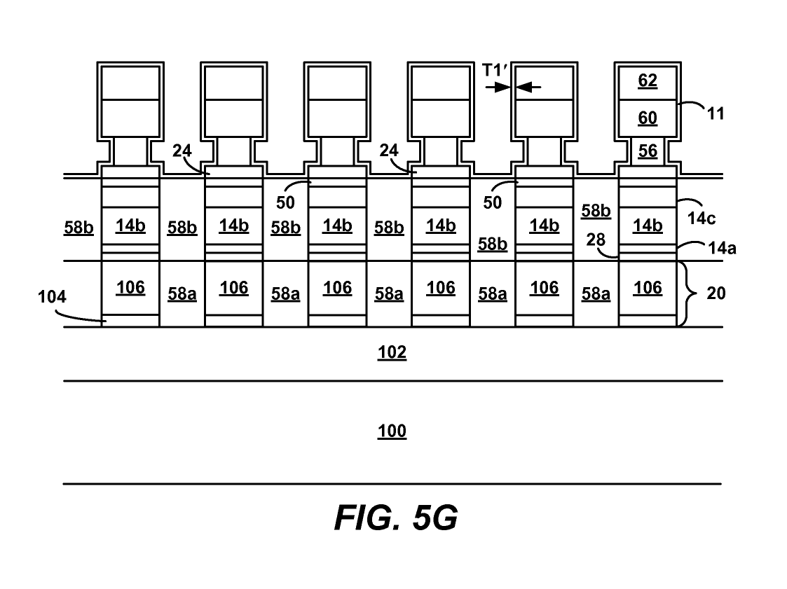

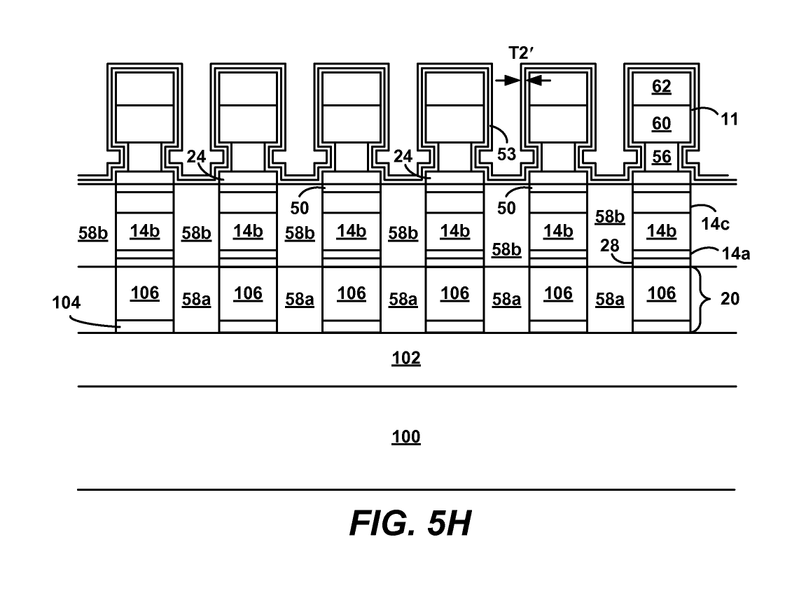

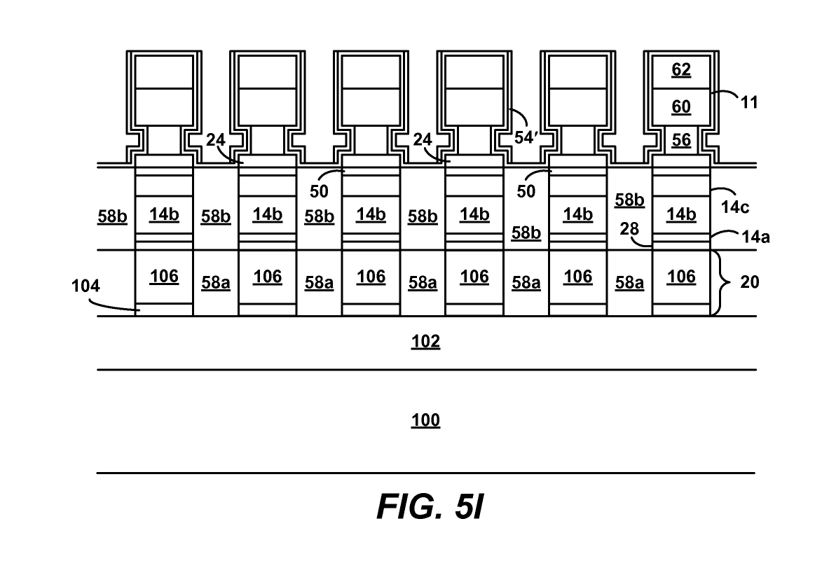

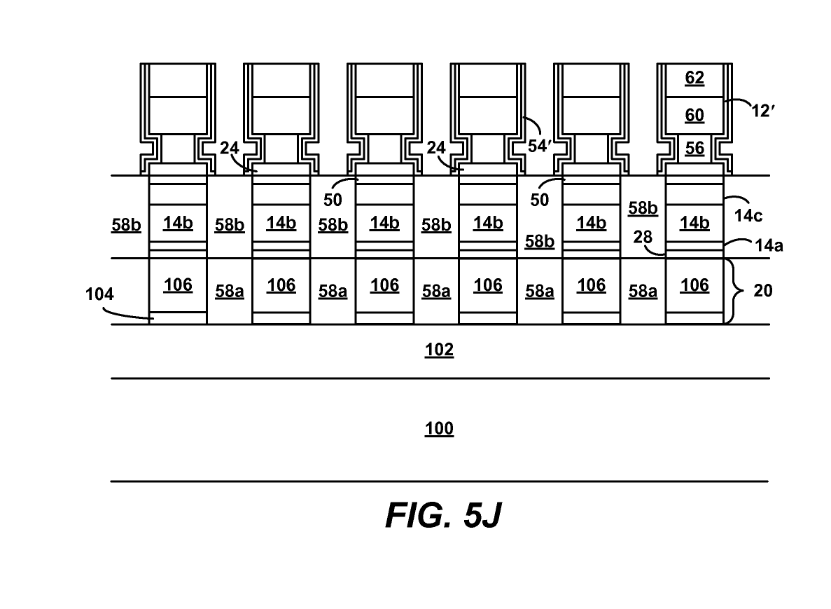

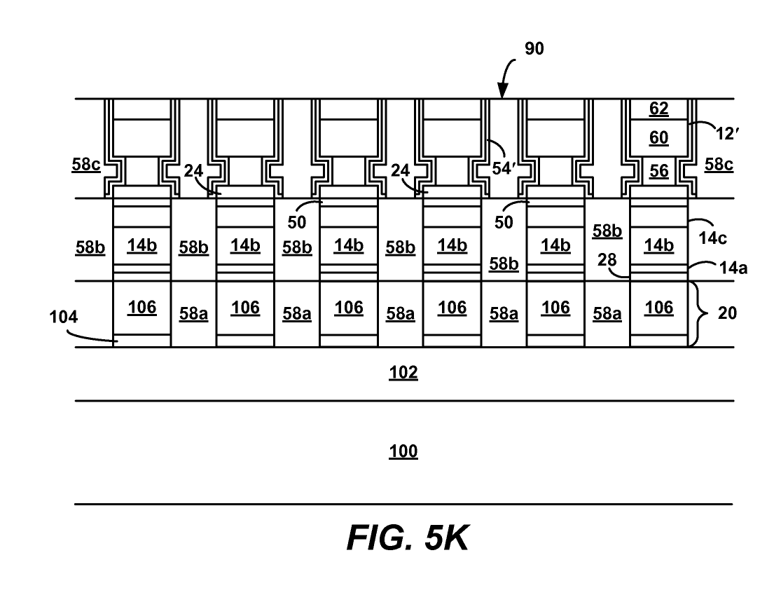

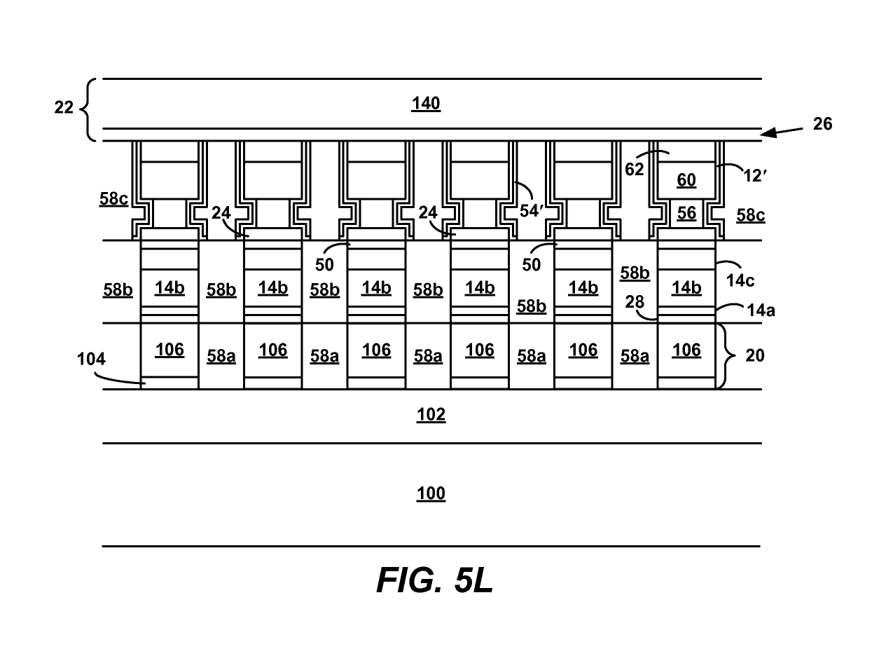

Referring now to FIGS. 5A-5L, an alternative exemplary method of forming an exemplary memory level in accordance with this invention is described. As will be described below, the first memory level includes a plurality of memory cells that each include a steering element and a reversible resistance switching element coupled to the steering element. Additional memory levels may be fabricated above the first memory level (as described previously with reference to FIGS. 2C-2D).

With reference to FIG. 5A, substrate 100 is shown as having already undergone several processing steps, and includes isolation layer 102, substantially parallel, substantially co-planar first conductors 20, dielectric layer 58a, and planar surface 110.

With reference to FIG. 5B, barrier layer 28, heavily doped n+ silicon layer 14a, lightly doped, intrinsic and/or unintentionally doped silicon layer 14b, p+ silicon layer 14c and silicide-forming metal layer 52 are formed over planarized top surface 110 of substrate 100, an RTA step is performed to form silicide layer 50, and barrier layer 24 is deposited over silicide-forming metal layer 52, such as described above in connection with FIG. 4B.

Next, first insulating layer 56 is deposited over barrier layer 24, second insulating layer 60 is deposited over first insulating layer 56, and barrier layer 62 is deposited over second insulating layer 60. As described above, first insulating layer 56 is fabricated from a different material than second insulating layer 60. The materials used to form first insulating layer 56 and second insulating layer 60 preferably are easy to etch, and have good etch selectivity between one another, and between each insulating material and dielectric materials, such as silicon dioxide. For example, silicon, silicon nitride, silicon oxide, alumina, other similar oxide/nitride, or other similar materials may be used to form first insulating layer 56 and second insulating layer 60.

In at least one embodiment, first insulating layer 56 includes approximately 200 to 500 angstroms, more generally 100 to 1000 angstroms of alumina, and second insulating layer 60 includes approximately 200 to 500 angstroms, more generally 100 to 1000 angstroms of silicon nitride. Other insulating materials and/or thicknesses may be used. Any suitable method may be used to form first insulating layer 56 and second insulating layer 60. For example, CVD, PVD, ALD, or the like may be employed.

Barrier layer 62 may include TiN, TaN, W, WN, molybdenum, or other similar material. In some embodiments, barrier layer 62 may be TiN with a thickness between about 500-1000 angstroms, although other materials and/or thicknesses may be used.

Next, barrier layer 62, second insulating layer 60, first insulating layer 56, barrier layer 24, silicide layer 50, diode layers 14a-14c and barrier layer 28 are patterned and etched to form pillars 132′ having a first width W1, as shown in FIG. 5C. For example, pillars 132′ may have a first width W1 between about 300 angstroms and about 1500 angstroms, more generally between about 200 angstroms and 5000 angstroms. Pillars 132′ may have about the same pitch and about the same width W1 as conductors 20 below, such that each pillar 132′ is formed on top of a conductor 20. Some misalignment may be tolerated.

For example, photoresist may be deposited, patterned using standard photolithography techniques, layers 62, 60, 56, 24, 50, 14a-14c, and 28 may be etched, and then the photoresist may be removed. Alternatively, a hard mask of some other material, for example silicon dioxide, may be formed on top of barrier layer 62, with BARC on top, then patterned and etched. Similarly, DARC may be used as a hard mask.

Pillars 132′ may be formed using any suitable masking and etching process. For example, layers 62, 60, 56, 24, 50, 14a-14c, and 28 may be patterned with about 1 micron to about 1.5 micron, more preferably about 1.2 micron to about 1.4 micron, of PR using standard photolithographic techniques. Thinner PR layers may be used with smaller critical dimensions and technology nodes. In some embodiments, an oxide hard mask may be used below the PR layer to improve pattern transfer and protect underlying layers during etching.

Any suitable etch chemistries, and any suitable etch parameters, flow rates, chamber pressures, power levels, process temperatures, and/or etch rates may be used.

After etching, pillars 132′ may be cleaned using a dilute hydrofluoric/sulfuric acid clean. Such cleaning, whether or not PR asking is performed before etching, may be performed in any suitable cleaning tool, such as a Raider tool, referenced above. Exemplary post-etch cleaning may include using ultra-dilute sulfuric acid (e.g., about 1.5-1.8 wt %) for about 60 seconds and ultra-dilute HF acid (e.g., about 0.4-0.6 wt) for 60 seconds. Megasonics may or may not be used.

Next, a dielectric layer 58b may be deposited over pillars 132′ to fill the voids between pillars 132′, resulting in the structure shown in FIG. 5D. For example, approximately 2000-7000 angstroms of silicon dioxide may be deposited. After top surface planarization by CMP, an etchback process is then used to remove excess dielectric material 58b to the top of silicide layer 50, forming a surface 88, resulting in the structure illustrated in FIG. 5E. Other dielectric materials such as silicon nitride, silicon oxynitride, low k dielectrics, etc., and/or other dielectric layer thicknesses may be used. Exemplary low k dielectrics include carbon doped oxides, silicon carbon layers, or the like.

As shown in FIG. 5F, first insulating regions 56 are narrowed using a shrink technique to form first insulating regions 56 having a width W3, and voids 87 between pillars. In some embodiments, first insulating regions 56 have a width W3 between about 200 angstroms and about 1400 angstroms, more generally between about 100 angstroms and about 4900 angstroms. Persons of ordinary skill in the art will understand that other W3 values may be used.

Preferably, shrink techniques are employed that selectively reduce the width of only first insulating regions 56 and preferably do not affect other layers of pillar 132′. Shrinking the width of first insulating regions 56 may be accomplished, for example, by laterally etching them.

For example, if first insulating regions 56 include alumina, any suitable alumina shrink technique may be used, such as one based on a selective wet etch chemistry, dry etch chemistry, or energetic plasma species. For instance, diluted HF solution or HF vapor may be used to selectively thin the width of first insulating regions 56. The amount of undercut of first insulating regions 56 may be controlled, for instance, by controlling the etching time or HF concentration.

Next, a layer 11 of carbon material may be conformally deposited in voids 87, resulting in the structure shown in FIG. 5G. For example, carbon layer 11 may be formed by using thermal CVD graphitic carbon to conformally deposit between about 10 angstroms and about 30 angstroms, more generally between about 7 angstroms and about 100 angstroms of thermal CVD graphitic carbon. Exemplary process parameters for forming thermal CVD graphitic carbon are described in Table 1 above. Persons of ordinary skill in the art will understand that other carbon-based materials, deposition methods and/or thicknesses may be used.

As illustrated in FIG. 5G, carbon layer 11 has a vertical sidewall thickness T1′. In some embodiments, carbon layer 11 has a vertical sidewall thickness T1′ of between about 10 angstroms and about 30 angstroms, and more preferably between about 7 angstroms and about 100 angstroms. Other thicknesses may be used.

As illustrated in FIG. 5H, a conformal dielectric layer 53 is deposited above carbon layer 11. Dielectric layer 53 may be formed using silicon nitride, silicon oxynitride, boron nitride, low k dielectrics, or other similar dielectric material. Exemplary low k dielectrics include carbon doped oxides, silicon carbon layers, or the like. Dielectric layer 53 has a vertical sidewall thickness T2′. In some embodiments, dielectric layer 54′ has a vertical sidewall thickness T2′ between about 50 angstroms and about 100 angstroms, more generally between about 30 angstroms and about 300 angstroms. Other thicknesses may be used. Any suitable method may be used to form layer 53. For example, PECVD, ALD, or the like may be employed.

Next an anisotropic etch is used to remove lateral portions of dielectric layer 53, leaving only sidewall portions 54′, as illustrated in FIG. 5I. For example, a sputter etch or other suitable process may be used to anisotropically etch dielectric layer 53. Other etch processes may be used.

A second anisotropic etch is used to remove lateral portions of carbon layer 11, leaving only sidewall portions as carbon element 12′, resulting in substantially parallel pillars, as illustrated in FIG. 5J. For example, a sputter etch or other suitable process may be used to anisotropically etch carbon layer 11.

Next, a dielectric layer 58c is deposited over substrate 100 to fill voids 87. For example, approximately 1500 to about 3500 angstroms of silicon dioxide may be deposited. Other dielectric materials such as silicon nitride, silicon oxynitride, low k dielectrics, etc., and/or other dielectric layer thicknesses may be used. Exemplary low k dielectrics include carbon doped oxides, silicon carbon layers, or the like. The structure is planarized using chemical mechanical polishing or an etchback process to remove excess dielectric material 58c and form a planar surface 90, resulting in the structure illustrated in FIG. 5K. Planarization may remove portions of dielectric sidewall liner 54′ and carbon element 12′. Accordingly, planar surface 90 includes exposed top surfaces of dielectric sidewall liner 54′ and carbon element 12′ separated by dielectric material 58c (as shown).

With reference to FIG. 5L, following planarization of dielectric layer 58c, a second conductor 22 is formed in a manner similar to the formation of first conductors 20. For example, in some embodiments, one or more barrier layers and/or adhesion layers 26 may be deposited prior to deposition of a conductive layer 140 used to form the second conductor 22.

Conductive layer 140 may be formed from any suitable conductive material such as tungsten, another suitable metal, heavily doped semiconductor material, a conductive silicide, a conductive silicide-germanide, a conductive germanide, or the like deposited by any suitable method (e.g., CVD, PVD, etc.). Barrier layers and/or adhesion layers 26 may include titanium nitride or another suitable layer such as tantalum nitride, tungsten nitride, combinations of one or more layers, or any other suitable material(s). In at least one embodiment, conductive layer 140 may comprise about 200 to about 2500 angstroms of tungsten, and barrier/adhesion layer 26 may comprise about 20 to about 500 angstroms of TiN. Other conductive layer and barrier layer materials and/or thicknesses may be used.

The deposited conductive layer 140 and barrier and/or adhesion layer 26, may be patterned and etched to form second conductors 22. In at least one embodiment, second conductors 22 are substantially parallel, substantially coplanar conductors that extend in a different direction than first conductors 20.

In other embodiments of the invention, second conductors 22 may be formed using a damascene process in which a dielectric layer is formed, patterned and etched to create openings or voids for conductors 22. The openings or voids may be filled with adhesion layer 26 and conductive layer 140 (and/or a conductive seed, conductive fill and/or barrier layer if needed). Adhesion layer 26 and conductive layer 140 then may be planarized to form a planar surface.

Following formation of second conductors 22, the resultant structure may be annealed to crystallize the deposited semiconductor material of diodes 14 (and/or to form silicide regions by reaction of the silicide-forming metal layer 52 with p+ region 14c), as described above.

The foregoing description discloses only exemplary embodiments of the invention. Modifications of the above disclosed apparatus and methods which fall within the scope of the invention will be readily apparent to those of ordinary skill in the art.

Accordingly, although the present invention has been disclosed in connection with exemplary embodiments thereof, it should be understood that other embodiments may fall within the spirit and scope of the invention, as defined by the following claims.

1. A reversible resistance-switching metal-carbon-metal (“MCM”) device comprising:
a first conducting layer;
a second conducting layer; and
a reversible resistance-switching element disposed between the first and second conducting layers, wherein the reversible resistance-switching element includes thermal CVD graphitic material and includes a highly resistive region that favors crack formation.

2. The device of claim 1, wherein the reversible resistance-switching element comprises a first portion having a first width, a second portion having a second width that is less than first width, and a third portion coupled between the first portion and the second portion.

3. The device of claim 2, wherein:
the first portion has a first resistance, the second portion has a second resistance, and the third portion has a third resistance; and
the third resistance is greater than the first resistance and the second resistance.

4. The device of claim 3, wherein the third resistance is between about 100 and 1000 times the first resistance and/or the second resistance.

5. The device of claim 1, further comprising a dielectric material, wherein the reversible resistance-switching element is disposed adjacent the dielectric material.

6. The device of claim 1, further comprising a first insulating layer and a second insulating layer, wherein the reversible resistance-switching element comprises a first portion disposed around the second insulating layer, and a second portion disposed around the first insulating layer.

7. The device of claim 1, wherein the reversible resistance-switching element comprises a thickness between about 7 and about 100 angstroms.

8. The device of claim 1, wherein the highly resistive region comprises sp³ defect lines.

9. A method of forming a reversible resistance-switching metal-insulator-metal (“MCM”) structure, the method comprising:
forming first and second conducting layers; and
forming a reversible resistance-switching element between the first and second conducting layers, wherein the reversible resistance-switching element includes a thermal CVD graphitic material and has a highly resistive region that favors crack formation.

10. The method of claim 9, wherein forming the reversible resistance-switching element comprises forming the reversible resistance-switching element with a first portion having a first width, a second portion having a second width that is less than first width, and a third portion coupled between the first portion and the second portion.

11. The method of claim 10, wherein:
the first portion has a first resistance, the second portion has a second resistance, and the third portion has a third resistance; and
the third resistance is greater than the first resistance and the second resistance.

12. The method of claim 11, wherein the third resistance is between about 100 and 1000 times the first resistance and the second resistance.

13. The method of claim 9, further comprising forming a dielectric material, wherein the reversible resistance-switching element is disposed around the dielectric material.

14. The method of claim 9, further comprising forming a first insulating layer and a second insulating layer, wherein the reversible resistance-switching element comprises a first portion disposed around the second insulating layer, and a second portion disposed around the first insulating layer.

15. The method of claim 9, wherein the reversible resistance-switching element comprises a thickness between about 7 and about 100 angstroms.

16. The method of claim 9, wherein the highly resistive region comprises includes sp³ defect lines.

17. An MCM formed according to the method of claim 9.

18. The method of claim 9, further comprising forming a steering element coupled in series with the reversible resistance-switching element.

19. The method of claim 18, wherein the steering element comprises a p-n or p-i-n diode.

20. The method of claim 18, wherein the steering element comprises a polycrystalline diode.

21. A memory cell formed according to the method of claim 18.

22. A method of forming a reversible resistance-switching metal-carbon-metal (“MCM”) structure, the method comprising:
forming a feature having a first width and a second width smaller than the first width; and
disposing a reversible resistance-switching element on a sidewall of the feature, wherein the reversible resistance-switching element includes thermal CVD graphitic material.

23. The method of claim 22, wherein the reversible resistance-switching element has a thickness between about 7 angstroms and about 100 angstroms.

24. The method of claim 22, wherein disposing the reversible resistance-switching element comprises depositing a conformal carbon material layer over the feature.

25. The method of claim 22, wherein disposing the reversible resistance-switching element comprises depositing carbon material by a chemical vapor deposition technique at a temperature between about 600° C. and about 1000° C.

26. The method of claim 22, further comprising depositing a conformal dielectric material layer over the reversible resistance-switching element.

27. An MCM formed according to the method of claim 22.

28. A method of forming a reversible resistance-switching metal-carbon-metal (“MCM”) structure, the method comprising:
forming a first conducting layer;
forming a first insulating material layer above the first conducting layer;
forming a second insulating material layer above the first insulating material layer, the second insulating material being different than the first insulating material;
forming a second conducting layer above the second insulating layer; and
disposing a reversible resistance-switching element on the second conducting layer, the first insulating material layer and the second insulating material layer, wherein the reversible resistance-switching element includes thermal CVD graphitic material.

29. The method of claim 28, wherein the reversible resistance-switching element comprises a first portion having a first resistance, a second portion having a second resistance, and a third portion coupled between the first portion and the second portion.

30. The device of claim 29, wherein the third resistance is greater than the first resistance and the second resistance.

31. The device of claim 30, wherein the third resistance is between about 100 and 1000 times the first resistance and/or the second resistance.

32. The method of claim 28, wherein the reversible resistance-switching element has a thickness between about 7 angstroms and about 1000 angstroms.

33. The method of claim 28, wherein disposing the reversible resistance-switching element comprises depositing a conformal carbon material layer on the second conducting layer, the first insulating material layer and the second insulating material layer.

34. The method of claim 28, wherein disposing the reversible resistance-switching element comprises depositing carbon material by a chemical vapor deposition technique at a temperature between about 600° C. and about 1000° C.

35. The method of claim 28, further comprising depositing a conformal dielectric material layer over the reversible resistance-switching element.

36. An MCM formed according to the method of claim 28.

37. A method of forming a memory cell, the method comprising:
forming a first conductor;
forming a feature above the first conductor, the feature having a first portion having a first width and a second portion having a second width smaller than the first width;
forming a reversible resistance-switching element on a sidewall of the feature, wherein the reversible resistance-switching element includes thermal CVD graphitic material; and
forming a second conductor above the reversible resistance-switching element.

38. The method of claim 37, wherein the reversible resistance-switching element has a thickness between about 7 angstroms and about 100 angstroms.

39. The method of claim 37, wherein disposing the reversible resistance-switching element comprises depositing a conformal carbon material layer over the feature.

40. The method of claim 37, wherein disposing the reversible resistance-switching element comprises depositing carbon material by a chemical vapor deposition technique at a temperature between about 600° C. and about 1000° C.

41. The method of claim 37, further comprising depositing a conformal dielectric material layer over the reversible resistance-switching element.

42. The method of claim 37, wherein forming the feature comprises:
forming a first sacrificial material layer;
forming a second sacrificial material layer above the first sacrificial layer, wherein the second sacrificial material is different from the first sacrificial material;
patterning and etching the first sacrificial material layer and the second sacrificial material layer to the first width;
shrinking the first sacrificial material layer to the second width;
forming a dielectric layer adjacent the first sacrificial material layer and the second sacrificial material layer; and
removing the first sacrificial material layer and the second sacrificial material layer to form a void in the dielectric layer.

43. The method of claim 37, further comprising forming a steering element coupled in series with the reversible resistance-switching element.

44. The method of claim 43, wherein the steering element comprises a p-n or p i n diode.

45. The method of claim 43, wherein the steering element comprises a polycrystalline diode.

46. A memory cell formed according to the method of claim 37.

47. A method of forming a memory cell, the method comprising:
forming a first conductor;
forming a first insulating material layer above the first conductor, wherein the first insulating material layer has a first width;
forming a second insulating material layer above the first insulating layer, wherein the second insulating material is different from the first insulating material, and wherein the second insulating material layer has the first width;
shrinking the first insulating material layer to a second width smaller than the first width;
forming a reversible resistance-switching element on the shrunken first insulating material layer and the second insulating material layer, wherein the reversible resistance-switching element includes thermal CVD graphitic material; and
forming a second conductor above the reversible resistance-switching element.

48. The method of claim 47, wherein the reversible resistance-switching element has a thickness between about 7 angstroms and about 100 angstroms.

49. The method of claim 47, wherein forming the reversible resistance-switching element comprises depositing a conformal carbon material layer over the shrunken first insulating material layer and the second insulating material layer.

50. The method of claim 47, wherein forming the reversible resistance-switching element comprises depositing carbon material by a chemical vapor deposition technique at a temperature between about 600° C. and about 1000° C.

51. The method of claim 47, further comprising depositing a conformal dielectric material layer over the reversible resistance-switching element.

52. The method of claim 47, further comprising forming a steering element coupled in series with the reversible resistance-switching element.

53. The method of claim 52, wherein the steering element comprises a p-n or p i n diode.

54. The method of claim 52, wherein the steering element comprises a polycrystalline diode.

55. A memory cell formed according to the method of claim 47.

56. A memory cell comprising:
a first conductor;
a feature disposed above the first conductor, the feature having a first portion having a first width and a second portion having a second width smaller than the first width;
a reversible resistance-switching element disposed on a sidewall of the feature, wherein the reversible resistance-switching element includes thermal CVD graphitic material; and
a second conductor disposed above the reversible resistance-switching element.

57. The memory cell of claim 56, wherein the reversible resistance-switching element has a thickness between about 7 angstroms and about 100 angstroms.

58. The memory cell of claim 56, further comprising a conformal dielectric material layer disposed over the reversible resistance-switching element.

59. The memory cell of claim 56, further comprising a steering element coupled in series with the reversible resistance-switching element.

60. The memory cell of claim 59, wherein the steering element comprises a p-n or p i n diode.

61. The memory cell of claim 59, wherein the steering element comprises a polycrystalline diode.

62. A memory cell comprising:
a first conductor;
a first insulating material layer disposed above the first conductor, wherein the first insulating material layer has a second width;
a second insulating material layer disposed above the first insulating layer, wherein the second insulating material is different from the first insulating material, and wherein the second insulating material layer has a first width;
a reversible resistance-switching element disposed on the first insulating material layer and the second insulating material layer, wherein the reversible resistance-switching element includes thermal CVD graphitic material; and
a second conductor disposed above the reversible resistance-switching element.

63. The memory cell of claim 62, wherein the reversible resistance-switching element has a thickness between about 7 angstroms and about 100 angstroms.

64. The memory cell of claim 62, further comprising a conformal dielectric material layer disposed over the reversible resistance-switching element.

65. The memory cell of claim 62, further comprising a steering element coupled in series with the reversible resistance-switching element.

66. The memory cell of claim 65, wherein the steering element comprises a p-n or p i n diode.

67. The memory cell of claim 65, wherein the steering element comprises a polycrystalline diode.
